(19) United States
(12) Patent Application Publication
(10) Pub. No.: US 2024/0122026 A1
(43) Pub. Date: Apr. 11, 2024

(54) DISPLAY DEVICE

(71) Applicant: Samsung Display Co., Ltd., Yongin-si (KR)

(72) Inventors: CHUL HYUN CHOI, Yongin-si (KR); MINJAE KIM, Yongin-si (KR); JAEMIN KIM, Yongin-si (KR); INHWA LEE, Yongin-si (KR)

(21) Appl. No.: 18/463,200

(22) Filed: Sep. 7, 2023

(30) Foreign Application Priority Data
Oct. 11, 2022 (KR) 10-2022-0129540

(51) Int. Cl. H10K 59/40; G06F 3/041; G06F 3/044; H10K 59/122

(52) U.S. Cl. CPC H10K 59/40; G06F 3/0412; G06F 3/0446; H10K 59/122; H10K 59/352

(57) ABSTRACT

A display device including a base layer having a display region defined along a first direction and a second direction that are orthogonal to each other, a plurality of first light emitting elements on the base layer, wherein each one of the first light emitting elements includes a first electrode, a second electrode on the first electrode, and a first emission layer between the first electrode and the second electrode, a pixel definition layer having a plurality of first emission openings each of which exposes the first electrode of a corresponding first light emitting element of the first light emitting elements, a thin encapsulation layer that covers the first light emitting elements and the pixel definition layer, and a sensing electrode on the thin encapsulation layer.

### CROSS-REFERENCE TO RELATED APPLICATION

This application claims priority to and the benefit of Korean Patent Application No. 10-2022-0129540 filed on Oct. 11, 2022 in the Korean Intellectual Property Office, the disclosure of which is hereby incorporated by reference in its entirety.

### BACKGROUND

### 1. Field

Aspects of the present invention relate to a display device.

### 2. Description of Related Art

There have been developed electronic devices such as smart phones, tablet computers, laptop computers, navigation systems, and smart televisions. These electronic devices have a display device for providing information. The electronic devices further include a variety of electronic modules in addition to a display panel.

It is desired that the display device satisfy display quality requirements for their intended use. Light generated from a light emitting element is outwardly emitted from the electronic device or the display device while producing various optical phenomena such as resonance and interference. This optical phenomenon may have an effect on quality of displayed images.

The above information disclosed in this Background section is only for enhancement of understanding of the background of the invention and therefore it may contain information that does not form the prior art.

### SUMMARY

According to some embodiments of the present invention are directed to a display device with improved display quality (e.g., color accuracy).

According to some embodiments of the present invention, there is provided a display device including: a base layer having a display region defined along a first direction and a second direction that are orthogonal to each other; a plurality of first light emitting elements on the base layer, wherein each one of the first light emitting elements includes a first electrode, a second electrode on the first electrode, and a first emission layer between the first electrode and the second electrode; a pixel definition layer having a plurality of first emission openings each of which exposes the first electrode of a corresponding first light emitting element of the first light emitting elements; a thin encapsulation layer that covers the first light emitting elements and the pixel definition layer; and a sensing electrode on the thin encapsulation layer, wherein the sensing electrode includes a conductive line that defines a plurality of first opening each corresponding to one of the first emission openings and each having an area greater than an area of each of the first emission openings, wherein the conductive line includes a first line section, a second line section, a third line section, and a fourth line section that correspond to one of the first emission openings, wherein the first line section and the second line section extend in a first diagonal direction that crosses the first direction and the second direction, the first line section and the second line section being spaced apart from each other in a second diagonal direction that is orthogonal to the first diagonal direction, a corresponding first emission opening of the first emission openings being between the first line section and the second line section in the second diagonal direction, wherein the third line section and the fourth line section extend in the second diagonal direction and are spaced apart from each other in the first diagonal direction, the corresponding first emission opening being between the first line section and the second line section in the second diagonal direction, and wherein a spacing distance between the second line section and the corresponding first emission opening is less than a spacing distance between the fourth line section and the corresponding first emission opening.

In some embodiments, the first direction extends at azimuthal angles of 0° and 180°, and when the first electrode of the corresponding first light emitting element is viewed at an azimuthal angle of 90° and a viewing angle of 60°, an area of the first electrode that is shielded by the second line section is greater than an area of the first electrode that is shielded by the fourth line section.

In some embodiments, the first line section, the second line section, the third line section, and the fourth line section have substantially the same line-width.

In some embodiments, an intersection region is between adjacent line sections of the first line section, the second line section, the third line section, and the fourth line section, and the intersection region has a line-width greater than line-widths of the adjacent line sections.

In some embodiments, the fourth line section has a line-width less than a line-width of the second line section.

In some embodiments, the line-width of the second line section is greater than a line-width of each of the first line section and the third line section, and the line-width of the fourth line section is less than the line-width of each of the first line section and the third line section.

In some embodiments, the display device further includes a plurality of second light emitting elements on the base layer, wherein each of the second light emitting elements includes a first electrode, a second electrode on the first electrode of the each of the second light emitting elements, and a second emission layer between the first and second electrodes of the each of the second light emitting elements, wherein the pixel definition layer further includes a plurality of second emission openings each of which exposes the first electrode of a corresponding second light emitting element of the second light emitting elements, wherein the sensing electrode further includes a plurality of second openings each corresponding to one of the second emission openings and each having an area greater than an area of each of the second emission openings, wherein the conductive line further includes a 1-1^{st} line section, a 2-1^{st} line section, a 3-1^{st} line section, and a 4-1^{st} line section that correspond to the second emission openings, wherein the 1-1^{st} line section and the 2-1^{st} line section are spaced apart from each other in the second diagonal direction across a corresponding second emission opening of the second emission openings, wherein the 3-1^{st} line section and the 4-1^{st} line section are spaced apart from each other in the first diagonal direction across the corresponding second emission opening, and wherein the 1-1^{st} line section, the 2-1^{st} line section, the 3-1^{st} line section, and the 4-1^{st} line section are spaced apart at substantially the same distance from the corresponding second emission opening.

In some embodiments, the first line section and the third line section are spaced apart at a first distance from the corresponding first emission opening, and wherein the 1-1^{st} line section and the corresponding second emission opening are spaced apart at the first distance from each other.

In some embodiments, the display device further includes a plurality of second light emitting elements on the base layer, wherein each of the second light emitting elements includes a first electrode, a second electrode on the first electrode of the each of the second light emitting elements, and a second emission layer between the first and second electrodes of the each of the second light emitting elements, wherein the second light emitting elements include a 2-1^{st} light emitting element, a 2-2^{nd} light emitting element, a 2-3^{rd} light emitting element, and a 2-4^{th} light emitting element that surround a corresponding first light emitting element of the first light emitting elements, wherein the 2-1^{st} light emitting element and the 2-2^{nd} light emitting element are spaced apart from each other in the second diagonal direction across the corresponding first light emitting element surrounded by the 2-1^{st} light emitting element, the 2-2^{nd} light emitting element, the 2-3^{rd} light emitting element, and the 2-4^{th} light emitting element, wherein the 2-3^{rd} light emitting element and the 2-4^{th} light emitting element are spaced apart from each other in the first diagonal direction across the corresponding first light emitting element surrounded by the 2-1^{st} light emitting element, the 2-2^{nd} light emitting element, the 2-3^{rd} light emitting element, and the 2-4^{th} light emitting element, and wherein the pixel definition layer further includes a 2-1^{st} emission opening, a 2-2^{nd} emission opening, a 2-3^{rd} emission opening, and a 2-4^{th} emission opening that respectively expose the first electrode of the 2-1^{st} light emitting element, the first electrode of the 2-2^{nd} light emitting element, the first electrode of the 2-3^{rd} light emitting element, and the first electrode of the 2-4^{th} light emitting element.

In some embodiments, the first line section is between the corresponding first emission opening and the 2-1^{st} emission opening, the second line section is between the corresponding first emission opening and the 2-2^{nd} emission opening, the third line section is between the corresponding first emission opening and the 2-3^{rd} emission opening, and the fourth line section is between the corresponding first emission opening and the 2-4^{th} emission opening.

In some embodiments, the first line section and the third line section are spaced apart at a first distance from the corresponding first emission opening, the first line section is spaced apart at the first distance from the 2-1^{st} emission opening, and the third line section is spaced apart at the first distance from the 2-3^{rd} emission opening.

In some embodiments, the second line section is spaced apart from the 2-2 nd emission opening at a distance greater than the first distance, and the fourth line section is spaced apart from the 2-4^{th} emission opening at a distance less than the first distance.

In some embodiments, each of the first emission openings has a substantially tetragonal shape in a plan view.

In some embodiments, each of the first emission openings is defined by a first edge, a second edge, a third edge, and a fourth edge, the first edge and the second edge extend in the first diagonal direction and face each other in the second diagonal direction, and the third edge and the fourth edge extend in the second diagonal direction and face each other in the first diagonal direction.

In some embodiments, each of the first light emitting elements generates red light.

According to some embodiments of the present invention, there is provided a display device including: a base layer having a display region defined by a first direction and a second direction that are orthogonal to each other a first light emitting element configured to generate a first source light; a 2-1^{st} light emitting element, a 2-2^{nd} light emitting element, a 2-3^{rd} light emitting element, and a 2-4^{th} light emitting element each of which is configured to generate a second source light and which surround the first light emitting element; a pixel definition layer that includes a first emission opening and a plurality of second emission openings, the first emission opening corresponding to the first light emitting element, the second emission openings corresponding to the 2-1^{st} light emitting element, the 2-2^{nd} light emitting element, the 2-3^{rd} light emitting element, and the 2-4^{th} light emitting element; a thin encapsulation layer that covers the first light emitting element, the 2-1^{st} light emitting element, the 2-2^{nd} light emitting element, the 2-3^{rd} light emitting element, the 2-4^{th} light emitting element, and the pixel definition layer; and a sensing electrode on the thin encapsulation layer, and including a conductive line including a first aperture corresponding to the first emission opening and a plurality of second opening that correspond to the second emission openings, the first aperture having an area greater than an area of the first emission opening, and each of the second opening having an area greater than an area of each of the second emission openings, wherein the conductive line includes a first line section between the first light emitting element and the 2-1^{st} light emitting element, a second line section between the first light emitting element and the 2-2^{nd} light emitting element, a third line section between the first light emitting element and the 2-3^{rd} light emitting element, and a fourth line section between the first light emitting element and the 2-4^{th} light emitting element, wherein the first line section and the second line section extend in a first diagonal direction that cross the first direction and the second direction, wherein the third line section and the fourth line section extend in a second diagonal direction orthogonal to the first diagonal direction, wherein at least one of the first line section and the third line section is spaced apart at a first distance from the first emission opening, wherein the second line section is spaced apart from the first emission opening at a distance less than the first distance, and wherein the fourth line section is spaced apart from the first emission opening at a distance greater than the first distance.

In some embodiments, the first line section is spaced apart at the first distance from one of the second emission openings that corresponds to the 2-1^{st} light emitting element, and the third line section is spaced apart at the first distance from one of the second emission openings that corresponds to the 2-3^{rd} light emitting element.

In some embodiments, the second line section is spaced apart at a distance greater than the first distance from one of the second emission openings that corresponds to the 2-2^{nd} light emitting element.

In some embodiments, the fourth line section is spaced apart at a distance less than the first distance from one of the second emission openings that corresponds to the 2-4^{th} light emitting element.

In some embodiments, the first line section, the second line section, the third line section, and the fourth line section have substantially the same line-width.

### BRIEF DESCRIPTION OF THE DRAWINGS

FIG. 1 illustrates a perspective view showing a display device according to some embodiments of the present invention.

FIG. 2 illustrates a cross-sectional view showing a display device according to some embodiments of the present invention.

FIG. 3A is an enlarged plan view showing a display region of a display panel according to some embodiments of the present invention.

FIG. 3B illustrates a cross-sectional view showing a display device according to some embodiments of the present invention.

FIG. 3C illustrates a plan view showing an input sensor according to some embodiments of the present invention.

FIG. 3D illustrates an enlarged plan view showing a portion of FIG. 3C according to some embodiments of the present invention.

FIGS. 4A and 4B illustrate diagrams showing a spherical coordinate system defined on a display device.

FIGS. 5A and 5B illustrate plan views showing an arrangement relationship between emission openings and a sensing electrode according to a comparative example.

FIG. 5C illustrates a graph showing a variation in color coordinate of a white image displayed on a display device according to a comparative example.

FIG. 6A illustrates a plan view showing an arrangement relationship between emission openings and a sensing electrode according to a comparative example.

FIG. 6B illustrates a cross-sectional view showing an emission path of a first source light.

FIG. 6C illustrates a graph showing a variation in color coordinate of a white image displayed on a display device according to a comparative example.

FIG. 7A illustrates a plan view showing an arrangement relationship between emission openings and a sensing electrode according to some embodiments of the present invention.

FIG. 7B illustrates a cross-sectional view showing an emission path of the first source light according to some embodiments of the present invention.

FIG. 7C illustrates a plan view showing a region shielded by a sensing electrode when a first emission region is seen from a first measurement point according to some embodiments of the present invention.

FIG. 7D illustrates a graph showing a variation in color coordinate of a white image displayed on a display device according to some embodiments of the present invention.

FIG. 8 illustrates a plan view showing an arrangement relationship between emission openings and a sensing electrode according to some embodiments of the present invention.

### DETAILED DESCRIPTION

Like numerals indicate like components. Moreover, in the drawings, thicknesses, ratios, and dimensions of components are exaggerated for effectively explaining the technical contents. The term “and/or” includes one or more combinations defined by associated components.

It will be understood that, although the terms first, second, etc. may be used herein to describe various components, these components should not be limited by these terms. These terms are only used to distinguish one component from another component. For example, a first component could be termed a second component, and vice versa without departing from the scope of the present invention. Unless the context clearly indicates otherwise, the singular forms are intended to include the plural forms as well.

Unless otherwise defined, all terms used herein including technical and scientific terms have the same meaning generally understood by one of ordinary skilled in the art. Also, terms as defined in dictionaries generally used should be understood as having meaning identical or meaning contextually defined in the art and should not be understood as ideally or excessively formal meaning unless definitely defined herein.

The following will now describe some embodiments of the present invention in conjunction with the accompanying drawings.

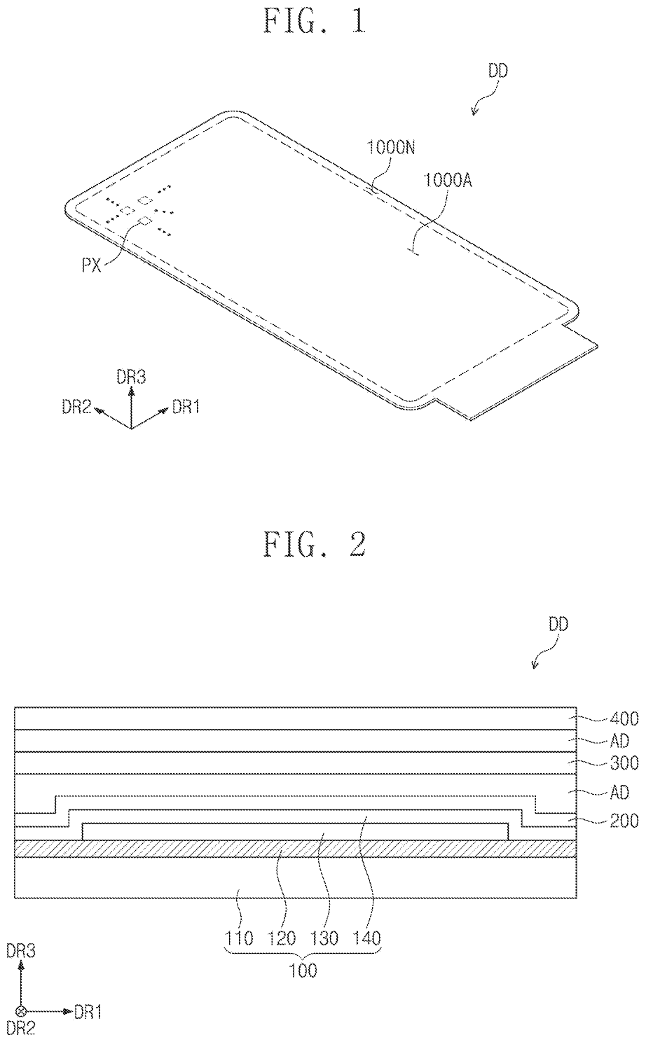

FIG. 1 illustrates a perspective view showing a display device DD according to some embodiments of the present invention.

The display device DD may generate an image and detect an external input. The display device DD may include a display region 1000A and a peripheral region 1000N. A pixel PX may be disposed on the display region 1000A. The pixel PX may include a first color pixel, a second color pixel, and a third color pixel that generate source light beams having different colors from each other.

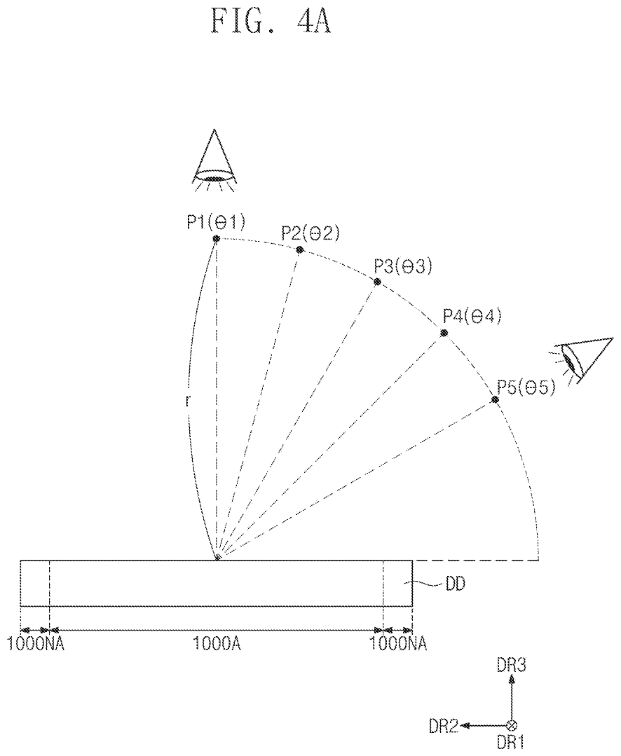

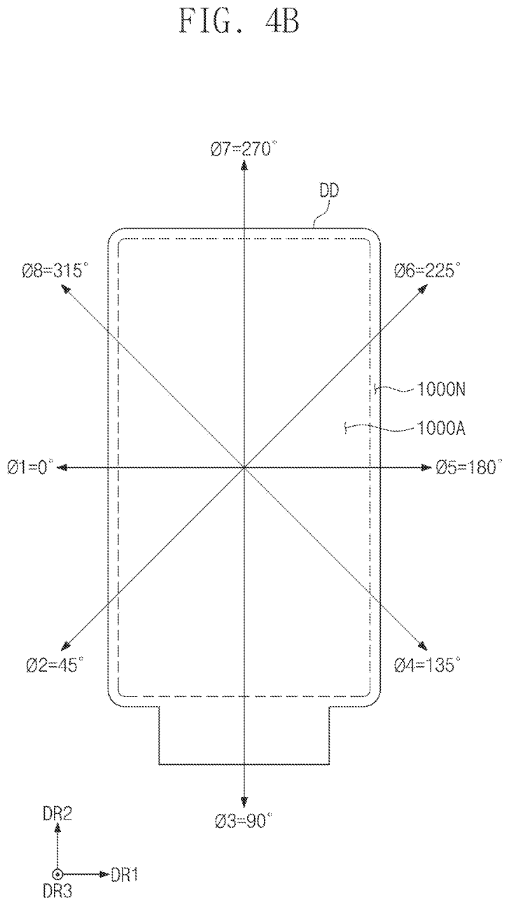

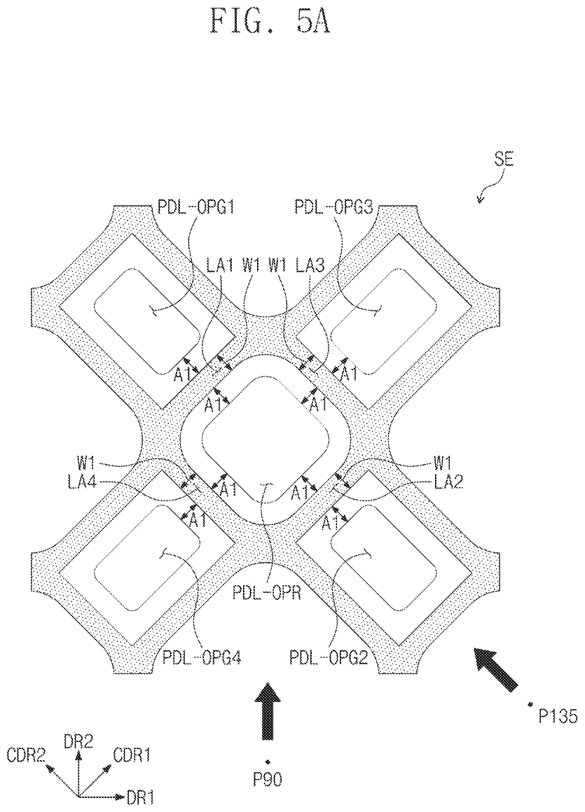

An image may be displayed on the display region 1000A. The display region 1000A may include a plane extending along a first direction DR1 and a second direction DR2 that are orthogonal to each other. The first direction DR1 may be defined as a direction that extends at an azimuthal angles of 0° and 180° which will discussed in FIG. 4B, and the second direction DR2 may be defined as a direction that extends at azimuthal angles of 90° and 270° which will be discussed in FIG. 4B.

The present example depicts by way of example the display region 1000A shaped like a rectangle in which a width in the first direction DR1 is less than that in the second direction DR2; however, embodiments of the present invention are not limited thereto. In some embodiments of the present invention, the width in the first direction DR1 may be greater than that in the second direction DR2.

The display region 1000A may further include curved surfaces that are bent from at least two sides of the plane. The display region 1000A, however, is not limited to the shape mentioned above. For example, the display region 1000A may include only the plane, or may further include a plurality of curved surfaces bent from at least two sides of the plane, for example, four curved surfaces bent from four sides of the plane. The display device DD may be a foldable display device or a rollable display device.

FIG. 2 illustrates a cross-sectional view showing the display device DD according to some embodiments of the present invention. Referring to FIG. 2, the display device DD may include a display panel 100, an input sensor 200, an anti-reflector 300, and a window 400.

The display panel 100 may be an emissive display panel. The display panel 100 may include a base layer 110, a drive element layer 120, a display element layer 130, and a thin encapsulation layer 140.

The base layer 110 may provide a base surface on which the drive element layer 120 is disposed. The base layer 110 may be a rigid substrate or a flexible substrate that can be bending, folding, or rolling. The base layer 110 may be a glass substrate, a metal substrate, or a polymer substrate. The present invention, however, is not limited thereto, and the base layer 110 may be an inorganic layer, an organic layer, or a composite material layer.

The base layer 110 may have a multi-layered structure. For example, the base layer 110 may include a first synthetic resin layer, an inorganic layer having a multi-layered or single-layered structure, and a second synthetic layer disposed on the inorganic layer having the multi-layered or single-layered structure. Each of the first and second synthetic resin layers may include a polyimide-based resin; however, embodiments of the present invention are not limited thereto.

The drive element layer 120 may be disposed on the base layer 110. The drive element layer 120 may include a dielectric layer, a semiconductor pattern, a conductive pattern, and a signal line. The drive element layer 120 may include a driver circuit of the pixel PX (referred to hereinafter as a pixel driver circuit) discussed in FIG. 1.

The display element layer 130 may be disposed on the drive element layer 120. The display element layer 130 may include a light emitting element of the pixel PX discussed in FIG. 1. For example, the light emitting element may include an organic light emitting material, an inorganic light emitting material, an organic-inorganic light emitting material, a quantum dot, a quantum rod, a micro-LED, a nano-LED, or the like.

The encapsulation layer 140 may be disposed on the display element layer 130. The encapsulation layer 140 may protect the display element layer 130 against moisture, oxygen, and foreign substances such as dust particles. The encapsulation layer 140 may include at least one inorganic layer. The encapsulation layer 140 may include a stacked structure in which an inorganic layer, an organic layer, and an inorganic layer are stacked on each other.

The input sensor 200 may be disposed on the display panel 100. The input sensor 200 may detect an external input applied from the outside. The external input may include a part of user's body, light, heat, pen, pressure, or any other of various suitable types of external input.

A series of processes may be employed to form the input sensor 200 on the display panel 100. In this case, the input sensor 200 may be directly disposed on the display panel 100. In this description, the phrase “component B is directly disposed on component A” may mean that no third component is disposed between component A and component B. For example, no adhesive layer may be disposed between the input sensor 200 and the display panel 100.

The anti-reflector 300 may reduce a reflectance of external light. The anti-reflector 300 may include an optical film. The optical film may include a polarizing film. The optical film may further include a retarder film. The retarder film may include one or both of a λ/2 retarder film and a λ/4 retarder film. The anti-reflector 300 and the input sensor 200 may be bonded through an adhesive layer AD.

In some embodiments of the present invention, the anti-reflector 300 may be directly disposed on the input sensor 200. The anti-reflector 300 may include color filters. The anti-reflector 300 may include a first color filter, a second color filter, and a third color filter that are disposed to respectively correspond to, or overlap with, the first color pixel, the second color pixel, and the third color pixel. The anti-reflector 300 may further include a black matrix. The black matrix may be disposed between the first color filter, the second color filter, and the third color filter. The black matrix may define a boundary between the first color filter, the second color filter, and the third color filter.

The window 400 may be disposed on the anti-reflector 300. The window 400 and the anti-reflector 300 may be bonded through an adhesive layer AD. The adhesive layer AD may be a pressure sensitive adhesive (PSA), an optically clear adhesive (OCA), or the like.

The window 400 may include at least one base layer. The base layer may be a glass substrate or a synthetic resin film. The window 400 may have a multi-layered structure. The window 400 may include a thin glass substrate and a synthetic resin film disposed on the thin glass substrate. The thin glass substrate and the synthetic resin film may be bonded through an adhesive layer, and the adhesive layer and the synthetic resin film may be separated from the thin glass substrate for replacement thereof.

In some embodiments of the present invention, the adhesive layer AD may be omitted between the window 400 and the anti-reflector 300, and the window 400 may be directly disposed on the anti-reflector 300. An organic material, an inorganic material, or a ceramic material may be coated on the anti-reflector 300.

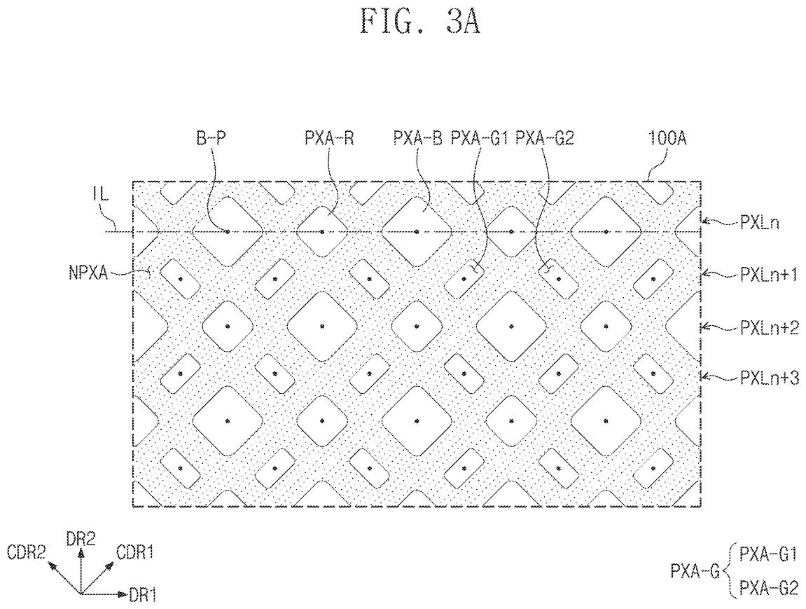

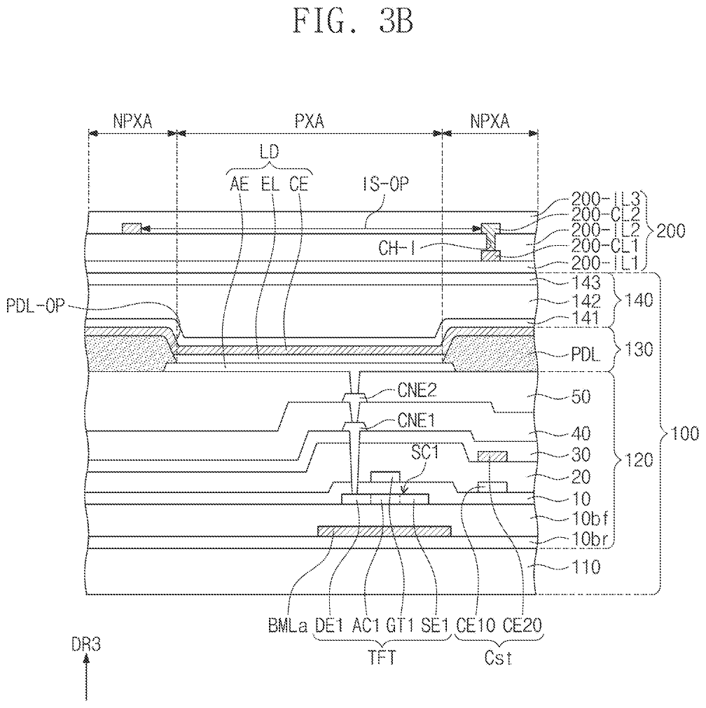

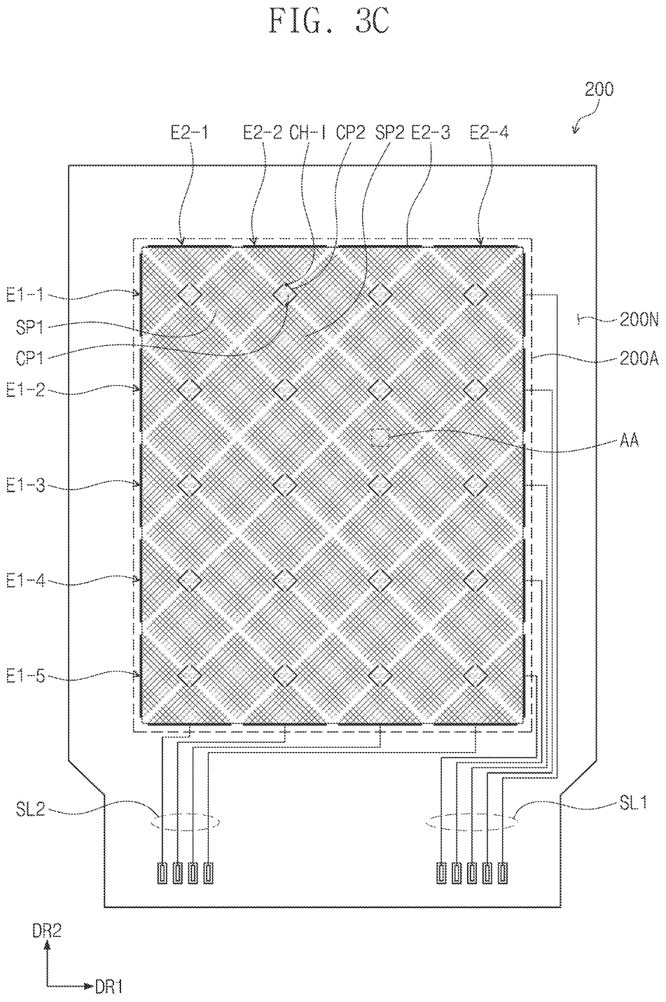

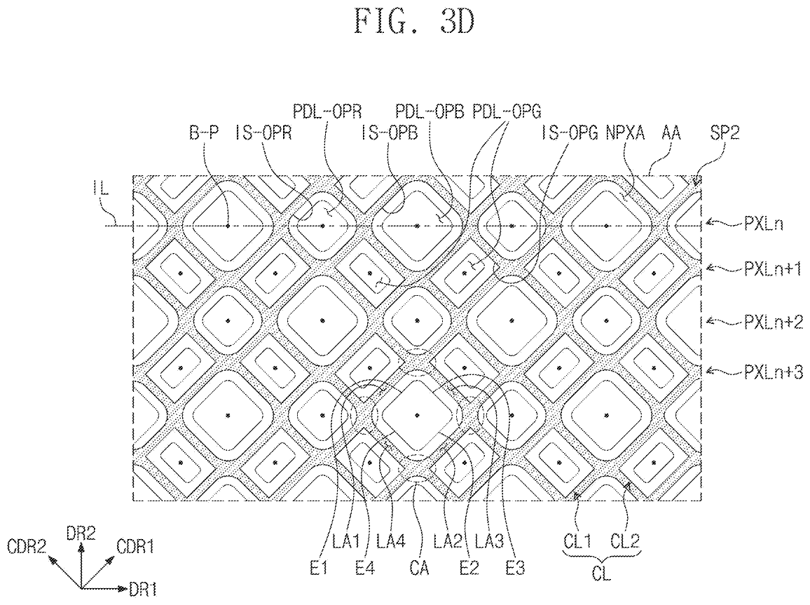

FIG. 3A illustrates an enlarged plan view showing a display region 100A of the display panel (see, e.g., 100 of FIG. 2A) according to some embodiments of the present invention. FIG. 3B illustrates a cross-sectional view showing the display device DD according to some embodiments of the present invention. FIG. 3C illustrates a plan view showing the input sensor 200 according to some embodiments of the present invention. FIG. 3D illustrates an enlarged plan view showing a portion of FIG. 3C according to some embodiments of the present invention.

Referring to FIG. 3A, the display region 100A may include a plurality of emission regions PXA-R, PXA-G, and PXA-B and a non-emission region NPXA between the plurality of emission regions PXA-R, PXA-G, and PXA-B. The plurality of emission regions PXA-R, PXA-G, and PXA-B may be classified into three groups of the emission regions PXA-R, PXA-G, and PXA-B. The three groups of the emission regions PXA-R, PXA-G, and PXA-B may be distinguished from each other based on a color of source light generated from a light emitting element (see, e.g., LD of FIG. 3B).

In the present embodiment, a first color emission region (or first emission region) PXA-R may provide red light, a second color emission region (or second emission region) PXA-G may provide green light, and a third color emission region (or third emission region) PXA-G may provide blue light. In some embodiments of the present invention, the display panel 100 may include three groups of emission regions that produce three primary colors such as yellow, magenta, and cyan.

The first, second, and third color emission regions PXA-R, PXA-G, and PXA-B may have different areas from each other. The present invention, however, is not limited thereto, and the first, second, and third color emission regions PXA-R, PXA-G, and PXA-B may have the same area as each other.

Each of the first, second, and third color emission regions PXA-R, PXA-G, and PXA-B may have a substantially polygonal shape. In this description, the expression “substantially polygonal shape” may include a mathematically defined polygon, a polygon with vertices on which curved lines are defined, or a polygon with blunt (or non-sharp) vertices. An emission region may be the same shape as that of an emission opening (see, e.g., PDL-OP of FIG. 3B) formed in the pixel definition layer (see, e.g., PDL of FIG. 3B), and shapes of vertices may be changed depending on etching properties of the pixel definition layer PDL.

In the present embodiment, the first color emission region PXA-R and the third color emission region PXA-B are illustrated to have their tetragonal shapes each of which is symmetric in each of the first direction DR1 and the second direction DR2. In addition, the second color emission region PXA-G is illustrated to have a tetragonal shape that is asymmetric in each of the first direction DR1 and the second direction DR2. The second color emission region PXA-G may be symmetric in a first diagonal direction CDR1 that intersects the first direction DR1 and the second direction DR2, and may also be symmetric in a second diagonal direction CDR2 that intersects the first diagonal direction CDR1. In some examples, the first diagonal direction CDR1 may be a direction that extends at azimuthal angles of 45° and 225° which may be discussed with respect to FIG. 4B. In some examples, the second diagonal direction CDR2 may be a direction that extends at azimuthal angles of 135° and 315° which may be discussed with respect to FIG. 4B.

The second color emission region PXA-G may include a first type second color emission region PXA-G1 (referred to hereinafter as a first type emission region) and a second type second color emission region PXA-G2 (referred to hereinafter as a second type emission region) that are symmetric in the second direction DR2. In some embodiments of the present invention, the second color emission region PXA-G may include only one of the first type emission region PXA-G1 and the second type emission region PXA-G2. In some embodiments of the present invention, the second color emission region PXA-G may be symmetric in each of the first direction DR1 and the second direction DR2.

In some embodiments of the present invention, the first color emission region PXA-R and the third color emission region PXA-B may each have a substantially square shape that is symmetric in each of the first direction DR1 and the second direction DR2. In some embodiments of the present invention, the second color emission region PXA-G may have a substantially rectangular shape. The first type emission region PXA-G1 and the second type emission region PXA-G2 may have substantially rectangular shapes that are symmetric in the second direction DR2.

Referring still to FIG. 3A, a plurality of emission regions PXA-B, PXA-R, and PXA-G may define a plurality of emission rows that are arranged along the second direction DR2. The emission rows may include an n^{th} emission row PXLₙ, an (n+1)^{th} emission row PXLₙ₊₁, an (n+2)^{th} emission row PXLₙ₊₂, and an (n+3)^{th} emission row PXLₙ₊₃ (where, n is a natural number). The four emission rows PXLₙ, PXLₙ₊₁, PXLₙ₊₂, and PXLₙ₊₃ may constitute a group, and a group of four emission rows PXLₙ, PXLₙ₊₁, PXLₙ₊₂, and PXLₙ₊₃ may be repeatedly arranged along the second direction DR2. Each of the four emission rows PXLₙ, PXLₙ₊₁, PXLₙ₊₂, and PXLₙ₊₃ may extend along the first direction DR1.

The n^{th} emission row PXLₙ may include the first color emission regions PXA-R and the third color emission regions PXA-B that are disposed alternately along the first direction DR1. The (n+2)^{th} emission row PXLₙ₊₂ may include the third color emission regions PXA-B and the first color emission regions PXA-R that are disposed alternately along the first direction DR1. The first color emission regions PXA-R and the third color emission regions PXA-B may be aligned along the second direction DR2.

An arrangement sequence of emission regions in the n^{th} emission row PXLₙ may be different from that of emission regions in the (n+2)^{th} emission row PXLₙ₊₂. The third color emission regions PXA-B and the first color emission regions PXA-R of the n^{th} emission row PXLₙ may be staggered with respect to the third color emission regions PXA-B and the first color emission regions PXA-R of the (n+2)^{th} emission row PXLₙ₊₂. It may appear that emission regions of the n^{th} emission row PXLₙ are shifted in the second direction DR2 by one emission region with respect to emission regions of the (n+2)^{th} emission row PXLₙ₊₂.

The second color emission regions PXA-G may be disposed in each of the (n+1)^{th} emission row PXLₙ₊₁ and the (n+3)^{th} emission row PXLₙ₊₃. The (n+1)^{th} emission row PXLₙ₊₁ may include the second type emission regions PXA-G2 and the first type emission regions PXA-G1 that are disposed alternately along the first direction DR1. The (n+3)^{th} emission row PXLₙ₊₃ may include the first type emission regions PXA-G1 and the second type emission regions PXA-G2 that are disposed alternately along the first direction DR1.

Emission regions of the n^{th} emission row PXLₙ may be staggered with respect to emission regions of the (n+1)^{th} emission row PXLₙ₊₁. Emission regions of the (n+2)^{th} emission row PXLₙ₊₂ may be staggered with respect to emission regions of the (n+3)^{th} emission row PXLₙ₊₃. An imaginary straight line IL may be provided on which are located centers B-P of emission regions disposed in each of four emission rows PXLₙ, PXLₙ₊₁, PXLₙ₊₂, and PXLₙ₊₃.

As a plurality of emission regions PXA-R, PXA-G, and PXA-B define the arrangement discussed above, four second color emission regions PXA-G may surround one first color emission region PXA-R. Two second color emission regions PXA-G may face each other in the first diagonal direction CDR1 across the first color emission region PXA-R, and another two color emission regions PXA-G may face each other in the second diagonal direction CDR2 across the first color emission region PXA-R. In addition, four second color emission regions PXA-G may surround one third color emission region PXA-B. Two second color emission regions PXA-G may face each other in the first diagonal direction CDR1 across the third color emission region PXA-B, and another two color emission regions PXA-G may face each other in the second diagonal direction CDR2 across the third color emission region PXA-B.

FIG. 3B depicts a cross-section of the display device DD, and the cross-section corresponds to one emission region PXA and the non-emission region NPXA around the emission region PXA. For example, FIG. 3B shows a cross-section of the display panel 100 and the input sensor 200. The emission region PXA of FIG. 3B may be any one of the emission regions PXA-B, PXA-R, and PXA-G of FIG. 3A.

The display panel 100 is illustrated to include a light emitting element LD and a transistor TFT connected to the light emitting element LD. The transistor TFT may be one of a plurality of transistors included in the pixel driver circuit. In the present example, the transistor TFT is described as a silicon transistor, however, the transistor TFT is not limited thereto, and may be any suitable transistor, such as a metal oxide transistor.

A barrier layer 10br may be disposed on the base layer 110. The barrier layer 10br may prevent or substantially reduce the introduction of foreign substances from the outside environment. The barrier layer 10br may include at least one inorganic layer. The barrier layer 10br may include a silicon oxide layer and a silicon nitride layer. A plurality of the silicon oxide layers and the silicon nitride layers may be provided, and the silicon oxide layers and the silicon nitride layers may be alternately stacked on one another.

A shield electrode BMLa may be disposed on the barrier layer 10br. The shield electrode BMLa may include metal. The shield electrode BMLa may include molybdenum (Mo) with good heat-resistance, a molybdenum-containing alloy, titanium (Ti), a titanium-containing alloy, and/or the like. The shield electrode BMLa may receive a bias voltage.

The shield electrode BMLa may prevent the transistor TFT from being affected by polarization-induced electric potential or substantially reduce the effects thereof. The shield electrode BMLa may prevent or substantially prevent external light from reaching the transistor TFT. In some embodiments of the present invention, the shield electrode BMLa may be a floating electrode that is isolated from (e.g., electrically isolated or insulated from) other electrodes or wiring lines.

A buffer layer 10bf may be disposed on the barrier layer 10br. The buffer layer 10bf may prevent metal elements or impurities from diffusing from the base layer 110 toward a semiconductor pattern SC1 disposed above, or substantially reduce such diffusion. The buffer layer 10bf may include at least one inorganic layer. The buffer layer 10bf may include a silicon oxide layer and a silicon nitride layer.

The semiconductor patterns SC1 may be disposed on the buffer layer 10bf. The semiconductor pattern SC1 may include a silicon semiconductor. For example, the silicon semiconductor may include amorphous silicon or polycrystalline silicon. The semiconductor pattern SC1 may include, for example, low-temperature polysilicon.

The semiconductor pattern SC1 may include a first region whose conductivity is high and a second region whose conductivity is low. The first region may be doped with n-type or p-type impurities. A p-type transistor may include a doped region implanted with p-type impurities, and an n-type transistor may include a doped region implanted with n-type impurities. The second region may be an undoped region or may be a doped region implanted with impurities whose concentration is less than that of impurities doped in the first region.

The first region may have conductivity greater than that of the second region, and may substantially serve as an electrode or a signal line. The second region may substantially correspond to an active section (or channel) of a transistor. For example, a portion of the semiconductor pattern SC1 may be an active section of a transistor, another portion of the semiconductor pattern SC1 may be a source or drain of the transistor, and still another portion of the semiconductor pattern SC1 may be a connection electrode or a connection signal line.

The transistor TFT may include a source section (or source) SE1, an active section (or channel) AC1, and a drain section (or drain) DE1 that are formed from the semiconductor pattern SC1. When viewed in a plan view, the source section SE1 and the drain section DE1 may extend in opposite directions from the active section AC1.

A first dielectric layer 10 may be disposed on the buffer layer 10bf. The first dielectric layer 10 may commonly overlap a plurality of pixels (see, e.g., PX of FIG. 1) and may cover the semiconductor pattern SC1. The first dielectric layer 10 may include one or both of an inorganic layer and an organic layer, and may have a single-layered or multi-layered structure. The inorganic layer may include at least one selected from aluminum oxide, titanium oxide, silicon oxide, silicon nitride, silicon oxynitride, zirconium oxide, and hafnium oxide. In the present embodiment, the first dielectric layer 10 may be a single-layered silicon oxide layer. Likewise, the first dielectric layer 10, a dielectric layer of the drive element layer 120 which will be discussed below may be one or both of an inorganic layer and an organic layer, and may have a single-layered or multi-layered structure. The inorganic layer may include at least one of the materials mentioned above; however, embodiments of the present invention are not limited thereto.

The transistor TFT may include a gate GT1 disposed on the first dielectric layer 10. The gate GT1 may be a portion of a metal pattern. The gate GT1 may overlap the active section AC1. The gate GT1 may serve as a mask in a process in which the semiconductor pattern SC1 is doped. The gate GT1 may include one or more of titanium (Ti), silver (Ag), a silver-containing alloy, molybdenum (Mo), a molybdenum-containing alloy, aluminum (Al), a aluminum-containing alloy, aluminum nitride (AlN), tungsten (W), tungsten nitride (WN), copper (Cu), indium tin oxide (ITO), and indium zinc oxide (IZO); however, embodiments of the present invention are not particularly limited thereto, and the gate GT1 may include any suitable material.

The first dielectric layer 10 may be provided thereon with a second dielectric layer 20 that covers the gate GT1. A third dielectric layer 30 may be disposed on the second dielectric layer 20. The second dielectric layer 20 and the third dielectric layer 30 may be provided therebetween with a second electrode CE20 of a storage capacitor Cst. In addition, a first electrode CE10 of the storage capacitor Cst may be disposed between the first dielectric layer 10 and the second dielectric layer 20.

A first connection electrode CNE1 may be disposed on the third dielectric layer 30. The first connection electrode CNE1 may be coupled to the drain section DE1 of the transistor TFT through a contact hole that penetrates the first, second, and third dielectric layers 10, 20, and 30.

A fourth dielectric layer 40 may be disposed on the third dielectric layer 30. A second connection electrode CNE2 may be disposed on the fourth dielectric layer 40. The second connection electrode CNE2 may be coupled to the first connection electrode CNE1 through a contact hole that penetrates the fourth dielectric layer 40. The fourth dielectric layer 40 may be provided thereon with a fifth dielectric layer 50 that covers the second connection electrode CNE2. There is illustrated, merely by way of example, a stacked structure in which the first to fifth dielectric layers 10 to 50 are stacked, however, additional conductive and dielectric layers may be further disposed in addition to the first to fifth dielectric layers 10 to 50.

Each of the fourth and fifth dielectric layers 40 and 50 may be an organic layer. For example, the organic layer may include a general universal polymer such as benzocyclobutene (BCP), polyimide, hexamethyldisiloxane (HMDSO), polymethylmethacrylate (PMMA), and polystyrene (PS), a polymer derivative having a phenol group, an acryl-based polymer, an imide-based polymer, an aryl ether-based polymer, an amide-based polymer, a fluoride-based polymer, a p-xylene-based polymer, a vinyl alcohol-based polymer, or any combination thereof.

The light emitting element LD may include a first electrode (an anode or a pixel electrode) AE, an emission layer EL, and a second electrode (cathode or common electrode) CE. The first electrode AE may be disposed on the fifth dielectric layer 50. The first electrode AE may be connected to the second connection electrode CNE2 through a contact hole that penetrates the fifth dielectric layer 50. The present invention, however, is not limited thereto, and the second connection electrode CNE2 may be connected to the second electrode CE. The first electrode AE may correspond to a common electrode, and the second electrode CE may be divided into a plurality of pieces each of which corresponds to a respective one of the emission regions PXA-B, PXA-R, and PXA-G of FIG. 3A. In addition, even though the light emitting element LD has the structure shown in FIG. 3B, the first electrode AE may be a cathode and the second electrode CE may be an anode (thus making up an inverted structure).

The first electrode AE may be a transflective electrode (e.g., an electrode that is partially transmissive and partially reflective), a transmissive electrode, or a reflective electrode. The first electrode AE may include a reflective layer formed of Ag, Mg, Al, Pt, Pd, Au, Ni, Nd, Ir, Cr, and/or the like, and a transmissive or transflective electrode layer formed on the reflective layer. The transmissive or transflective electrode layer may include at least one selected from indium tin oxide (ITO), indium zinc oxide (IZO), indium gallium zinc oxide (IGZO), zinc oxide (ZnO), indium oxide (In₂O₃), and aluminum-doped zinc oxide (AZO). For example, the first electrode AE may include a stacked structure of ITO/Ag/ITO (i.e., having a structure in which a layer of Ag is sandwiched between two ITO layers).

A pixel definition layer PDL may be disposed on the fifth dielectric layer 50. The pixel definition layer PDL may be an organic layer. In some embodiments of the present invention, the pixel definition layer PDL may exhibit light-absorbing properties and may have a black color. The pixel definition layer PDL may include a black coloring agent. The black coloring agent may include a black dye or a black pigment. The black coloring agent may include a carbon black, metal such as chromium, or oxide thereof. The pixel definition layer PDL may correspond to a light-shield pattern having light-shield properties.

The pixel definition layer PDL may cover a portion of the first electrode AE. For example, the pixel definition layer PDL may have an emission opening PDL-OP that exposes a portion of the first electrode AE. The emission opening PDL-OP may define the emission region PXA of the display panel 100.

The pixel definition layer PDL may have a first emission opening, a second emission opening, and a third emission opening that correspond to the first color emission region PXA-R, the second color emission region PXA-G, and the third color emission region PXA-B that are discussed with reference to FIG. 3A. FIG. 3B depicts one emission opening PDL-OP representative of the first emission opening, the second emission opening, and the third emission opening.

A hole control layer may be disposed between the first electrode AE and the emission layer EL. The hole control layer may include a hole transport layer and may further include a hole injection layer. An electrode control layer may be disposed between the emission layer EL and the second electrode CE. The electrode control layer may include an electrode transport layer and may further include an electrode injection layer. The hole control layer and the electron control layer may commonly overlap the first color emission region PXA-R, the second color emission region PXA-G, the third color emission region PXA-B, and the non-emission region NPXA that are discussed with reference to FIG. 3A.

First light emitting elements, second light emitting elements, and third light emitting elements may be disposed to correspond to the first color emission regions PXA-R, the second color emission regions PXA-G, and the third color emission regions PXA-B of FIG. 3A. The first light emitting element, the second light emitting element, and the third light emitting element may include their emission layers EL different from each other. For example, the first light emitting element may include a first emission layer that generates first source light, the second light emitting element may include a second emission layer that generates second source light, and the third light emitting element may include a third emission layer that generates third source light.

The encapsulation layer 140 may be disposed on the display element layer 130. The encapsulation layer 140 may encapsulate the light emitting element LD and the pixel definition layer PDL. The encapsulation layer 140 may include an inorganic layer 141, an organic layer 142, and an inorganic layer 143 that are sequentially stacked; however, layers included in the encapsulation layer 140 are not limited thereto.

The inorganic layers 141 and 143 may protect the display element layer 130 from moisture and oxygen, and the organic layer 142 may protect the display element layer 130 from foreign substances such as dust particles. The inorganic layers 141 and 143 may include a silicon nitride layer, a silicon oxynitride layer, a silicon oxide layer, a titanium oxide layer, and/or an aluminum oxide layer. The organic layer 142 may include an acryl-based organic layer; however, embodiments of the present invention are not limited thereto, and the inorganic layers 141 and 143 and the organic layer 142 may include any suitable material.

The input sensor 200 may include a first dielectric layer 200-IL, a first conductive pattern layer 200-CL1, a second dielectric layer 200-IL2, a second conductive pattern layer 200-CL2, and a third dielectric layer 200-IL3. The first dielectric layer 200-IL1 may be directly disposed on the encapsulation layer 140.

One or both of the first and third dielectric layers 200-IL1 and 200-L3 may be omitted from some embodiments of the present invention. When the first dielectric layer 200-IL1 is omitted, the first conductive pattern layer 200-CL1 may be directly disposed on a dielectric layer at top of the encapsulation layer 140. The third dielectric layer 200-IL3 may be replaced with an adhesive layer or a dielectric layer of the anti-reflector 300 disposed on the input sensor 200. In some embodiments of the present invention, the input sensor 200 may include only one of the first conductive pattern layer 200-CL1 and the second conductive pattern layer 200-CL2.

The first conductive pattern layer 200-CL1 may include a first conductive pattern, and the second conductive pattern layer 200-CL2 may include a second conductive pattern. Each of the first and second conductive patterns may include regularly arranged patterns. In the following description, the same reference numeral or symbol may be allocated to the first conductive pattern layer 200-CL1 and the first conductive pattern, and the same reference numeral or symbol may be allocated to the second conductive pattern layer 200-CL2 and the second conductive pattern.

Each of the first conductive pattern 200-CL1 and the second conductive pattern 200-CL2 may have a single-layered structure or a multi-layered structure in which a plurality of layers are stacked along the third direction DR3. The conductive pattern having the multi-layered structure may include at least two selected from transparent conductive layers and metal layers. The conductive pattern having the multi-layered structure may include metal layers including different metal materials. The transparent conductive layer may include indium tin oxide (ITO), indium zinc oxide (IZO), zinc oxide (ZnO), indium tin zinc oxide (ITZO), poly(3,4-ethylenedioxythiophene) or PEDOT, metal nano-wires, graphene, and/or the like. The metal layer may include molybdenum, silver, titanium, copper, aluminum, or any alloy thereof.

The first conductive pattern 200-CL1 and the second conductive pattern 200-CL2 may overlap the non-emission region NPXA. The first conductive pattern 200-CL1 may have an aperture IS-OP that corresponds to the emission region PXA. The aperture IS-OP may have an area greater than that of the emission opening PDL-OP.

In the present examples, each of the first to third dielectric layers 200-IL1 to 200-IL3 may include an inorganic layer or an organic layer. The first to third dielectric layers 200-IL1 to 200-IL3 may include an inorganic layer. The inorganic layer may include silicon oxide, silicon nitride, silicon oxynitride, and/or the like.

In some embodiments of the present invention, at least one selected from the first to third dielectric layers 200-IL1 to 200-IL3 may be an organic layer. For example, the third dielectric layer 200-IL3 may include an organic layer. The organic layer may include at least one selected from an acryl-based resin, a methacryl-based resin, polyisoprene, a vinyl-based resin, an epoxy-based resin, a urethane-based resin, a cellulose-based resin, a siloxane-based resin, a polyimide-based resin, a polyamide-based resin, and a perylene-based resin.

Referring to FIG. 3C, the input sensor 200 may include a sensing region 200A and a non-sensing region 200N adjacent to the sensing region 200A. The sensing region 200A and the non-sensing region 200N may respectively correspond to the display region 1000A and the peripheral region 1000N that are shown in FIG. 1. The input sensor 200 may include first sensing electrodes E1-1 to E1-5 and

second sensing electrodes E2-1 to E2-4 that are disposed on the sensing region 200A and are insulated from each other while crossing each other. An external input may be detected by calculating a variation in mutual capacitance formed between the first sensing electrodes E1-1 to E1-5 and the second sensing electrodes E2-1 to E2-4.

A self-capacitance type input sensor 200 may include sensing electrodes that do not cross each other. In the present examples, it may be sufficient that the input sensor 200 includes a sensing electrode, and no limitation is imposed on an operation mechanism of the input sensor 200.

The input sensor 200 may include first signal lines SL1 that are disposed on the non-sensing region 200N and electrically connected to the first sensing electrodes E1-1 to E1-5, and may also include second signal lines SL2 that are disposed on the non-sensing region 200N and electrically connected to the second sensing electrodes E2-1 to E2-4. Each or a combination of the first and second conductive patterns 200-CL1 and 200-CL2 may define the first sensing electrodes E1-1 to E1-5, the second sensing electrodes E2-1 to E2-4, the first signal lines SL1, and the second signal lines SL2.

Each of the first and second sensing electrodes E1-1 to E1-5 and E2-1 to E2-4 may include a plurality of conductive lines that cross each other. A plurality of conductive lines may define a plurality of opening, and each of the first and second sensing electrodes E1-1 to E1-5 and E2-1 to E2-4 may have a mesh shape. Each of the plurality of opening may be defined like the aperture IS-OP shown in FIG. 3B.

One or more of the first and second sensing electrodes E1-1 to E1-5 and E2-1 to E2-4 may have a single unitary shape. In FIG. 3C, there are illustrated by way of example the first sensing electrodes E1-1 to E1-5 having a single unitary shape. The first sensing electrodes E1-1 to E1-5 may include sensing parts SP1 and intermediate parts CP1. A portion of the second conductive pattern 200-CL2 may correspond to the first sensing electrodes E1-1 to E1-5.

Each of the second sensing electrodes E2-1 to E2-4 may include sensing patterns SP2 and bridge patterns (or connection patterns) CP2. Two adjacent sensing patterns SP2 may be connected to two bridge patterns CP2 through a contact hole CH-I that penetrates the second dielectric layer (see, e.g., 200-IL2 of FIG. 3B). A portion of the second conductive pattern 200-CL2 may correspond to the sensing patterns SP2. A portion of the first conductive pattern 200-CL1 may correspond to the bridge patterns CP2.

In some embodiments, the bridge patterns CP2 is formed from the first conductive pattern 200-CL1 shown in FIG. 3B, and the first sensing electrodes E1-1 to E1-5 and the sensing patterns SP2 are formed from the second conductive pattern 200-CL2 shown in FIG. 3B. In some examples, the first sensing electrodes E1-1 to E1-5 and the sensing patterns SP2 may be formed from the first conductive pattern 200-CL1 shown in FIG. 3B, and the bridge patterns CP2 may be formed from the second conductive pattern 200-CL2 shown in FIG. 3B.

Ones of the first signal lines SL1 and the second signal lines SL2 may transfer (e.g., transmit) a transmitting signal for detecting an external input from an external circuit, and others of the first signal lines SL1 and the second signal lines SL2 may provide (e.g., supply) an external circuit with a receiving signal that represents a variation in capacitance between the first sensing electrodes E1-1 to E1-5 and the second sensing electrodes E2-1 to E2-4.

A portion of the second conductive pattern 200-CL2 may correspond to the first signal lines SL1 and the second signal lines SL2. The first signal lines SL1 and the second signal lines SL2 may have a multi-layered structure, and may include a first-layered line formed from the first conductive pattern 200-CL1 and a second-layered line formed from the second conductive pattern 200-CL2. The first-layered line and the second-layered line may be connected through a contact hole that penetrates the second dielectric layer (see, e.g., 200-IL2 of FIG. 3B).

FIG. 3D illustrates an enlarged view showing the sensing pattern SP2 for explaining the first sensing electrodes E1-1 to E1-5 and the second sensing electrodes E2-1 to E2-4 that have their mesh shapes shown in FIG. 3C. Non-shown portions of the first and second sensing electrodes E1-1 to E1-5 and E2-1 to E2-4 may have the same shape as that of the sensing pattern SP2 shown in FIG. 3D. A line open region of a conductive line CL1 and CL2 shown in FIG. 3D may be defined at a boundary between the first sensing electrodes E1-1 to E1-5 and the second sensing electrodes E2-1 to E2-4 shown in FIG. 3C.

The following will describe the sensing pattern SP2 representative of the first sensing electrodes E1-1 to E1-5 and the second sensing electrodes E2-1 to E2-4. Referring to FIG. 3D, the sensing pattern SP2 may have first, second, and third opening IS-OPR, IS-OPG, and IS-OPB that are defined to correspond to first, second, and third emission openings PDL-OPR, PDL-OPG, and PDL-OPB, respectively.

The sensing pattern SP2 may overlap the non-emission region NPXA and include a conductive line CL. The conductive line CL may include first line segments CL1 that extend in the first diagonal direction CDR1 and second line segments CL2 that extend in the second diagonal direction CDR2. The first line segments CL1 and the second line segments CL2 may intersect each other to define the first, second, and third opening IS-OPR, IS-OPG, and IS-OPB that correspond to the first, second, and third emission openings PDL-OPR, PDL-OPG, and PDL-OPB. Therefore, the sensing pattern SP2 may have a grid or mesh shape. Each of the first line segments CL1 might not have a perfect straight shape that extends in the first diagonal direction CDR1, but may include a plurality of straight sections and a plurality of curved (e.g., inflection) sections. Each of the second line segments CL2 may also include a plurality of straight sections and a plurality of curved (e.g., inflection) sections.

The sensing pattern SP2 may include a first line section LA1 and a second line section LA2 that face each other in the second diagonal direction CDR2 across each of the first, second, and third opening IS-OPR, IS-OPG, and IS-OPB, and may also include a third line section LA3 and a fourth line section LA4 that face each other in the first diagonal direction CDR1 across each of the first, second, and third opening IS-OPR, IS-OPG, and IS-OPB. The first line section LA1 and the second line section LA2 may each be a straight section that extends in the first diagonal direction CDR1, and the third line section LA3 and the fourth line section LA4 may each be a straight section that extends in the second diagonal direction CDR2. The first emission opening PDL-OPR may be surrounded by the first line section LA1, the second line section LA2, the third line section LA3, and the fourth line section LA4.

The first line section LA1 and the second line section LA2 may be portions of the first line segments CL1, and the third line section LA3 and the fourth line section LA4 may be portions of the second line segments CL2. Each of the first, second, third, and fourth line sections LA1, LA2, LA3, and LA4 may have a uniform line-width. The line-width of each of the first line section LA1, the second line section LA2, the third line section LA3, and the fourth line section LA4 may be about 2 micrometers to about 8 micrometers.

The first line section LA1, the second line section LA2, the third line section LA3, and the fourth line section LA4 may be disposed adjacent to a first edge E1, a second edge E2, a third edge E3, and a fourth edge E4, respectively, that define a corresponding one of the first, second, third, and fourth emission openings PDL-OPR, PDL-OPG, and PDL-OPB. The first line section LA1, the second line section LA2, the third line section LA3, and the fourth line section LA4 may be disposed parallel to the first edge E1, the second edge E2, the third edge E3, and the fourth edge E4, respectively. The first edge E1 and the second edge E2 may extend in the first diagonal direction CDR1, and the third edge E3 and the fourth edge E4 may extend in the second diagonal direction CDR2.

In the present embodiment, the sensing pattern SP2 is illustrated as having a regular interval between each of the line sections LA1, LA2, LA3, and LA4 and its corresponding one of the edges E1, E2, E3, and E4. When each of the first, second, and third emission openings PDL-OPR, PDL-OPG, and PDL-OPB has a different shape from that of a corresponding one of the first, second, and third opening IS-OPR, IS-OPG, and IS-OPB, an irregular interval may be formed between each of the line sections LA1, LA2, LA3, and LA4 and its corresponding one of the edges E1, E2, E3, and E4.

An intersection region CA may be disposed between adjacent ones of the first, second, third, and fourth line sections LA1, LA2, LA3, and LA4. The intersection region CA may have a line-width greater than that of its adjacent line section. The difference in line-width may be observed by comparing the line-width of the first line section LA1 and the line-width of the intersection region CA defined between the first line section LA1 and the third line section LA3.

FIGS. 4A and 4B illustrate diagrams showing a spherical coordinate system defined on the display device DD.

As shown in FIGS. 4A and 4B, a spherical coordinate system may be defined on the display device DD. The origin of the spherical coordinate system may be aligned with a center of the display region 1000A in the display device DD. The spherical coordinate system may be used to distinguish from each other the points that measure display quality (e.g., color accuracy) of the display device DD.

The spherical coordinate system may be expressed by (r, θ, ϕ) wherein the symbol “r” may indicate a distance from the origin to a measurement point, the symbol “θ” may denote an angle between a z-axis (or a normal axis of the display device DD) and a straight line defined between the origin and the measurement point, and the symbol “ϕ” may signify an angle between an x-axis (or a horizontal axis that passes through a center of the display device DD) and a projection line obtained when the straight line defined between the origin and the measure point is projected onto an x-y plane (or a front surface of the display device DD). For convenience of description, the symbol “θ” may be defined as a viewing angle, and the symbol “ϕ” may be defined as an azimuthal angle.

FIG. 4A depicts five measurement points, or first to fifth measurement points P1 to P5. The first measurement point P1 may be defined to have a first viewing angle θ1 of 0°. Second, third, fourth, and fifth viewing angles θ2, θ3, θ4, and θ5 may have their certain angles relative to the z-axis (or the normal axis of the display device DD). Angles of 15°, 30°, 45°, and 60° may be respectively given as the second, third, fourth, and fifth viewing angles θ2, θ3, θ4, and θ5 of the second, third, fourth, and fifth measurement points P2, P3, P4, and P5. In some examples, angles of 20°, 40°, 60°, and 80° may be respectively given as the second, third, fourth, and fifth viewing angles θ2, θ3, θ4, and θ5 of the second, third, fourth, and fifth measurement points P2, P3, P4, and P5. In other examples, angles of 10°, 20°, 30°, and 40° may be respectively given as the second, third, fourth, and fifth viewing angles θ2, θ3, θ4, and θ5 of the second, third, fourth, and fifth measurement points P2, P3, P4, and P5.

FIG. 4B depicts by way of example eight azimuthal angles ϕ1 to ϕ8. First to eighth azimuthal angles ϕ1 to ϕ8 may be 0°, 45°, 90°, 135°, 180°, 225°, 270°, and 315°, respectively.

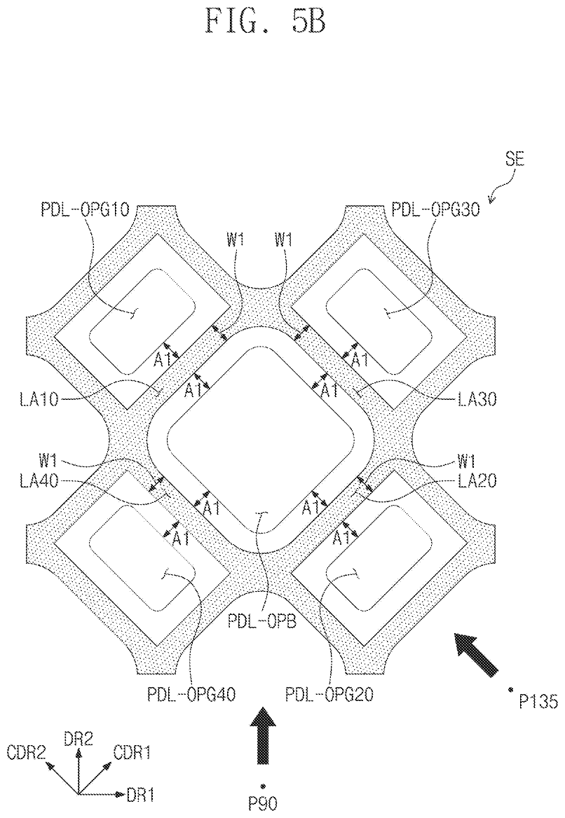

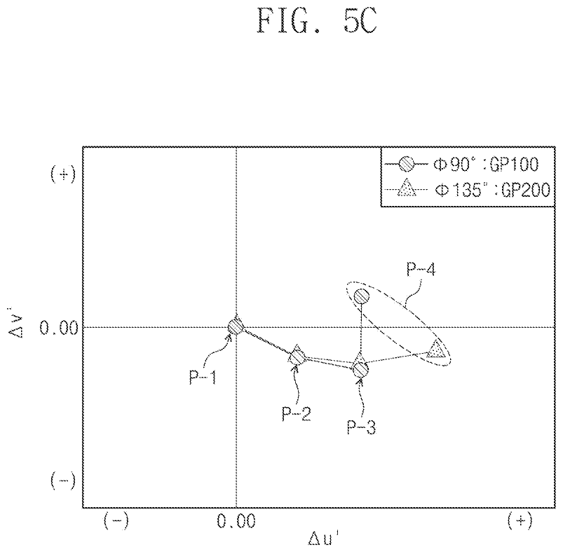

FIGS. 5A and 5B illustrate plan views showing an arrangement relationship between the emission openings PDL-OPR, PDL-OPG, and PDL-OPB and a sensing electrode SE according to a comparative example. FIG. 5C illustrates a graph showing a variation in color coordinate of a white image displayed on a display device according to a comparative example.

The sensing electrodes SE of FIGS. 5A and 5B may be different portions of the sensing pattern SP2 illustrated in FIG. 3D and are depicted in more detail than is shown in FIG. 3D.

FIG. 5A depicts one first emission opening PDL-OPR and four second emission openings PDL-OPG1 to PDL-OPG4 that surround the first emission opening PDL-OPR, and FIG. 5B depicts one third emission opening PDL-OPB and four second emission openings PDL-OPG10 to PDL-OPG40 that surround the third emission opening PDL-OPB. A further discussion of the components shown in FIG. 3D will be provided in the following description. In the following, the second emission openings PDL-OPG1 to PDL-OPG4 and PDL-OPG10 to PDL-OPG40 may be defined as 2-1^{st} emission openings PDL-OPG1 and PDL-OPG10, 2-2^{nd} emission openings PDL-OPG2 and PDL-OPG20, 2-3^{rd} emission openings PDL-OPG3 and PDL-OPG30, and 2-4th emission openings PDL-OPG4 and PDL-OPG40, respectively. The second light emitting elements, each of which generates the second source light, may be correspondingly disposed on the 2-1^{st} emission openings PDL-OPG1 and PDL-OPG10, the 2-2^{nd} emission openings PDL-OPG2 and PDL-OPG20, the 2-3^{rd} emission openings PDL-OPG3 and PDL-OPG30, and the 2-4^{th} emission openings PDL-OPG4 and PDL-OPG40.

Referring to FIG. 5A, the 2-1^{st} emission opening PDL-OPG1 and the 2-2 nd emission opening PDL-OPG2 may face each other in the second diagonal direction CDR2, and the first emission opening PDL-OPR may be disposed between the 2-1^{st} emission opening PDL-OPG1 and the 2-2^{nd} emission opening PDL-OPG2 in the second diagonal direction CDR2. The 2-3^{rd} emission opening PDL-OPG3 and the 2-4th emission opening PDL-OPG4 may face each other in the first diagonal direction CDR1, and the first emission opening PDL-OPR may be disposed between the 2-3^{rd} emission opening PDL-OPG3 and the 2-4^{th} emission opening PDL-OPG4 in the first diagonal direction CDR1.

The sensing electrode SE may include the first line section LA1, the second line section LA2, the third line section LA3, and the fourth line section LA4 that are disposed around the first emission opening PDL-OPR. The first line section LA1 may be disposed between the 2-1^{st} emission opening PDL-OPG1 and the first emission opening PDL-OPR (e.g., in the second diagonal direction CDR2). The second line section LA2 may be disposed between the 2-2^{nd} emission opening PDL-OPG2 and the first emission opening PDL-OPR (e.g., in the second diagonal direction CDR2). The third line section LA3 may be disposed between the 2-3^{rd} emission opening PDL-OPG3 and the first emission opening PDL-OPR (e.g., in the first diagonal direction CDR1). The fourth line section LA4 may be disposed between the 2-4^{th} emission opening PDL-OPG4 and the first emission opening PDL-OPR (e.g., in the first diagonal direction CDR1). In some examples, a line-width W1 of each of the first line section LA1, the second line section LA2, the third line section LA3, and the fourth line section LA4 may be about 3 micrometers. In other examples, the line-width W1 may range from about 2 micrometers to about 5 micrometers.

Substantially the same distance may be provided between the first emission opening PDL-OPR and each of the 2-1^{st} emission opening PDL-OPG1, the 2-2 nd emission opening PDL-OPG2, the 2-3^{rd} emission opening PDL-OPG3, and the 2-4th emission opening PDL-OPG4 that surround the first emission opening PDL-OPR. The distance therebetween may range from about 15 micrometers to about 20 micrometers. For example, a distance between the 2-1^{st} emission opening PDL-OPG1 and the 2-2^{nd} emission opening PDL-OPG2 in the second diagonal direction CDR2 may be about 15 micrometers to about 20 micrometers. Further, a distance between the 2-3^{rd} emission opening PDL-OPG3 and the 2-4^{th} emission opening PDL-OPG4 in the first diagonal direction CDR1 may be about 15 micrometers to about 20 micrometers.

The first line section LA1, the second line section LA2, the third line section LA3, and the fourth line section LA4 may be spaced apart at the same distance from the first emission opening PDL-OPR. A first distance A1 may be provided as an interval between the first emission opening PDL-OPR and each of the first line section LA1, the second line section LA2, the third line section LA3, and the fourth line section LA4. The first distance A1 may range from about 3 micrometers to about 11 micrometers.

The same distance may be provided as an interval between each of the first line section LA1, the second line section LA2, the third line section LA3, and the fourth line section LA4 and a corresponding one of (e.g., a nearest one of) the 2-1^{st} emission opening PDL-OPG1, the 2-2^{nd} emission opening PDL-OPG2, the 2-3^{rd} emission opening PDL-OPG3, and the 2-4^{th} emission opening PDL-OPG4. The first distance A1 may be provided as an interval between each of the first line section LA1, the second line section LA2, the third line section LA3, and the fourth line section LA4 and a corresponding one of (e.g., a nearest one of) the 2-1^{st} emission opening PDL-OPG1, the 2-2^{nd} emission opening PDL-OPG2, the 2-3^{rd} emission opening PDL-OPG3, and the 2-4^{th} emission opening PDL-OPG4.

Referring to FIG. 5B, the 2-1^{st} emission opening PDL-OPG10 and the 2-2 nd emission opening PDL-OPG20 may face each other in the second diagonal direction CDR2, and the third emission opening PDL-OPB may be disposed between the 2-1^{st} emission opening PDL-OPG10 and the 2-2^{nd} emission opening PDL-OPG20 in the second diagonal direction CDR2. The sensing electrode SE may include a 1-1^{st} line section LA10, a 2-1^{st} line section LA20, a 3-1^{st} line section LA30, and a 4-1^{st} line section LA40 that are disposed around the third emission opening PDL-OPB. The 1-1^{st} line section LA10 may be disposed between the 2-1^{st} emission opening PDL-OPG10 and the third emission opening PDL-OPB (e.g., in the second diagonal direction CDR2). The 2-1^{st} line section LA20 may be disposed between the 2-2^{nd} emission opening PDL-OPG20 and the third emission opening PDL-OPB (e.g., in the second diagonal direction CDR2). In some examples, a line-width W1 of each of the 1-1^{st} line section LA10, the 2-1^{st} line section LA20, the 3-1^{st} line section LA30, and the 4-1^{st} line section LA40 may be about 3 micrometers. In other examples, the line-width W1 may range from about 2 micrometers to about 5 micrometers.

Although the first line section LA1, the second line section LA2, the third line section LA3, and the fourth line section LA4 disposed around the first emission opening PDL-OPR shown in FIG. 5A are illustrated and discussed, to distinguish from each other in the interest of convenience of description, these line sections may be merely different portions of the sensing electrode SE and may all correspond to a line section, and this may hold true for the 1-1^{st} line section LA10, the 2-1^{st} line section LA20, the 3-1^{st} line section LA30, and the 4-1^{st} line section LA40 disposed around the third emission opening PDL-OPB shown in FIG. 5B. Four second emission openings PDL-OPG1 to PDL-OPG4 shown in FIG. 5A each correspond to the second emission opening PDL-OPG and different reference numerals are allocated thereto to distinguish from each other, and this may hold true for four second emission openings PDL-OPG10 to PDL-OPG40.

Substantially the same distance may be provided between the third emission opening PDL-OPB and each of four second emission openings PDL-OPG10 to PDL-OPG40 that surround the third emission opening PDL-OPB. The distance therebetween may range from about 15 micrometers to about 20 micrometers. For example, a distance between the 2-1^{st} emission opening PDL-OPG10 and the 2-2 nd emission opening PDL-OPG20 in the second diagonal direction CDR2 may be about 15 micrometers to about 20 micrometers. Further, a distance between the 2-3^{rd} emission opening PDL-OPG30 and the 2-4^{th} emission opening PDL-OPG4 in the first diagonal direction CDR1 may be about 15 micrometers to about 20 micrometers.

The 1-1^{st} line section LA10, the 2-1^{st} line section LA20, the 3-1^{st} line section LA30, and the 4-1^{st} line section LA40 may be spaced apart at the same distance from the third emission opening PDL-OPB. A first distance A1 may be provided as an interval between the third emission opening PDL-OPB and each of the 1-1^{st} line section LA10, the 2-1^{st} line section LA20, the 3-1^{st} line section LA30, and the 4-1^{st} line section LA40. The same distance, such as the first distance A1, may be provided as an interval between each of the 1-1^{st} line section LA10, the 2-1^{st} line section LA20, the 3-1^{st} line section LA30, and the 4-1^{st} line section LA40 and a corresponding one (e.g., a nearest one of) of the 2-1^{st} emission opening PDL-OPG10, the 2-2^{nd} emission opening PDL-OPG20, the 2-3^{rd} emission opening PDL-OPG30, and the 2-4^{th} emission opening PDL-OPG40.

A first measurement point P90 and a second measurement point P135 are depicted in FIGS. 5A and 5B. The first measurement point P90 and the second measurement point P135 may have different azimuthal angles. For example, the first measurement point P90 may have an azimuthal angle of 90°, and the second measurement point P135 may have an azimuthal angle of 135°.

When the display device (see, e.g., DD of FIG. 4B) having the sensing electrode SE shown in FIGS. 5A and 5B was viewed from the first measurement point P90, no or negligible white angular dependency (WAD) was generated based on a viewing angle. In contrast, a relatively large white angular dependency (WAD) was generated at a specific viewing angle when viewed from the second measurement point P135. This is illustrated in the graph of FIG. 5C. Further, no white angular dependency was detected when measured at various measurement points having azimuthal angles other than 135°. It is assumed that an optical film contributes to the generation of white angular dependency at only a specific azimuthal angle. It is estimated that an optical axis of a polarizing film stretched in a particular direction causes light having a peculiar wavelength range to be more greatly provided at specific azimuthal and viewing angles.

FIG. 5C depicts a color-coordinate variation (Δu′, Δv′) based on azimuthal and viewing angles. A color coordinate measured at a measurement point (or a first point which will be discussed below) having an azimuthal angle of 90° and a viewing angle of 0° may be a reference of the color-coordinate variation (Δu′, Δv′). The color-coordinate variation (Δu′, Δv′) was expressed by a color coordinate (u′, v′) of the International Commission on Illumination (CIE) 1976 standard colorimetric system.

At the first measurement point (see, e.g., P90 of FIGS. 5A and 5B) having an azimuthal angle of 90°, color coordinates of a white image were measured while changing a viewing angle. The color coordinates of a white image were measured at four sites P-1, P-2, P-3, and P-4 having viewing angles of 0°, 30°, 45°, and 60°. A first graph GP100 may indicate the color-coordinate variation (Δu′, Δv′) at four sites P-1, P-2, P-3, and P-4 each having an azimuthal angle of 90°.

In addition, at the second measurement point (see P135 of FIGS. 5A and 5B) having an azimuthal angle of 135°, color coordinates of a white image were measured while changing the viewing angle. The color coordinates of a white image were measured at four sites P-1, P-2, P-3, and P-4 having viewing angles of 0°, 30°, 45°, and 60°. A second graph GP200 may indicate the color-coordinate variation (Δu′, Δv′) at four sites P-1, P-2, P-3, and P-4 each having an azimuthal angle of 135°.

When the first graph GP100 and the second graph GP200 are compared with each other, large white angular dependency was generated at a fourth site P-4. An increase in Δu′ may denote that a white image is measured as a reddish white image. This situation where users perceive the color of a white image differently based on viewing angles may indicate a reduction in display quality (e.g., color accuracy).

According to some embodiments of the present invention, the sensing electrode SE may cause interference at a specific azimuthal angle with respect to a white image to reduce the color-coordinate variation (Δu′, Δv′) based on viewing angles. The sensing electrode SE may be designed to induce interference only along an emission path of source light at a specific azimuthal angle. In addition, the sensing electrode SE may be designed to bring interference only along an emission path of one of the first source light, the second source light, and the third source light.

It is described in the present embodiments that users perceive a reddish white image that is shifted at a measurement point having an azimuthal angle of 135° and a viewing angle of 60°; however, embodiments of the present invention are not limited thereto. Further, a white image measured at a certain point may be a bluish white image, a greenish white image, or the like.

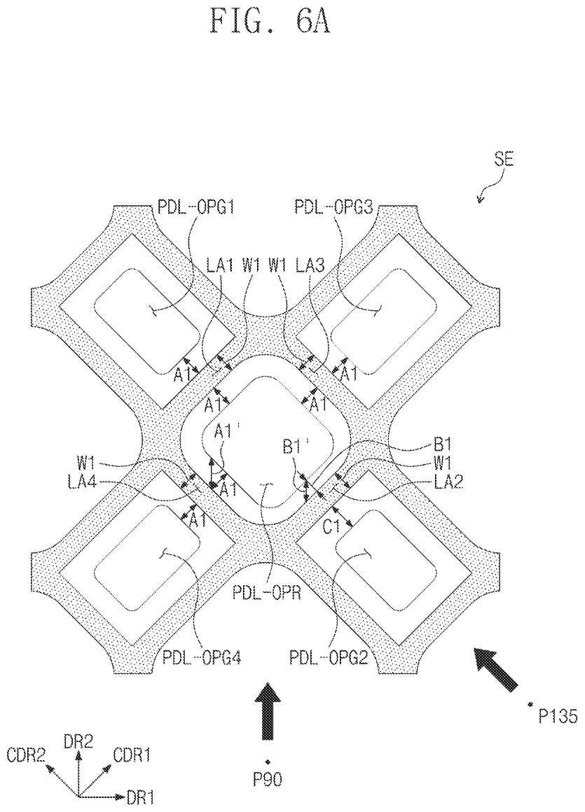

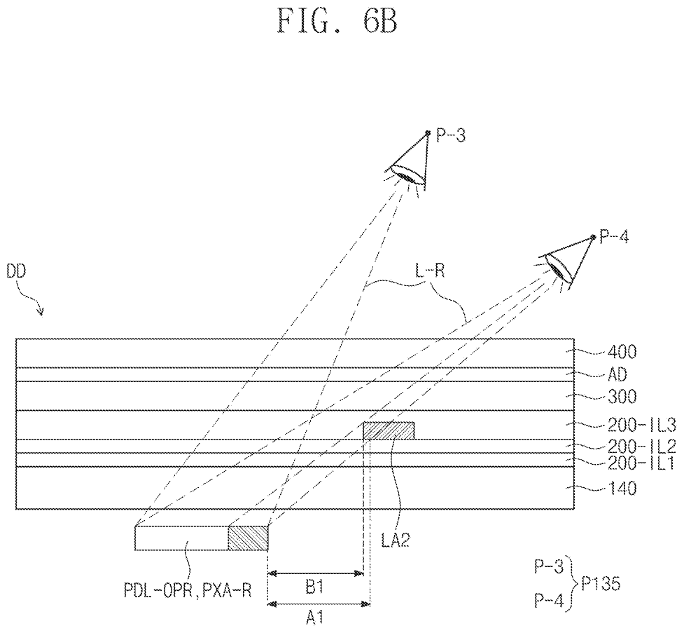

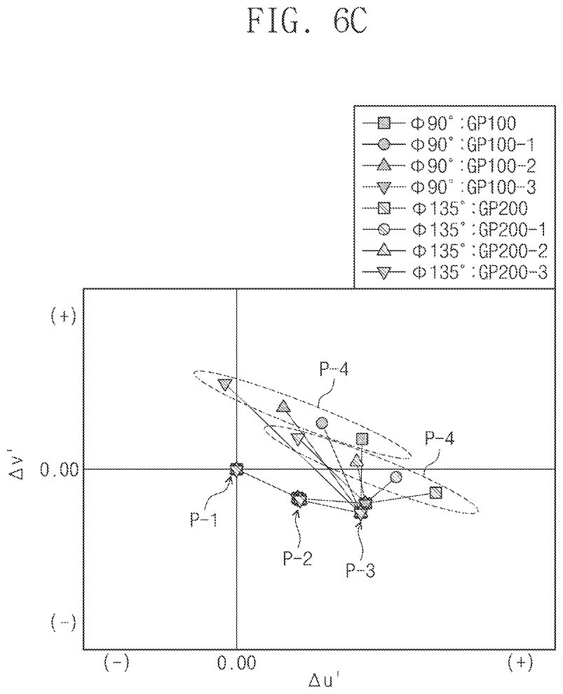

FIG. 6A illustrates a plan view showing an arrangement relationship between the emission openings PDL-OPR, PDL-OPG, and PDL-OPB and the sensing electrode SE according to a comparative example. FIG. 6B illustrates a cross-sectional view showing an emission path of first source light. FIG. 6C illustrates a graph showing a variation in color coordinate of a white image displayed on a display device according to a comparative example. In the interest of brevity, the following description will focus on a difference between the arrangement relationship shown in FIG. 5A (or the arrangement relationship between the emission openings PDL-OPR, PDL-OPG, and PDL-OPB and the sensing electrode SE shown in FIG. 5A) and the arrangement relationship shown in FIG. 6A (or the arrangement relationship between the emission openings PDL-OPR, PDL-OPG, and PDL-OPB and the sensing electrode SE shown in FIG. 6A).

The case where the reddish white image is measured, as discussed with reference to FIGS. 5A to 5C, FIG. 6A, depicts the sensing electrode SE that allows a white image to reduce a redshift. The sensing electrode SE according to the some embodiments may have an arrangement relationship that is the same as that shown in FIG. 5B, or different from the arrangement relationship of the 1-1^{st} line section LA10, the 2-1^{st} line section LA20, the 3-1^{st} line section LA30, and the 4-1^{st} line section LA40 with respect to the third emission opening PDL-OPB. When a bluish white image is measured, the sensing electrode SE that allows a white image to reduce a blueshift may have an arrangement relationship different from that shown in FIG. 5B, or different from the arrangement relationship of the 1-1^{st} line section LA10, the 2-1^{st} line section LA20, the 3-1^{st} line section LA30, and the 4-1^{st} line section LA40 with respect to the third emission opening PDL-OPB. As discussed below, the sensing electrode SE may have an arrangement relationship of the first line section LA1, the second line section LA2, the third line section LA3, and the fourth line section LA4 with respect to the first emission opening PDL-OPR, and the arrangement relationship may be applied to an arrangement relationship of the 1-1^{st} line section LA10, the 2-1^{st} line section LA20, the 3-1^{st} line section LA30, and the 4-1^{st} line section LA40 with respect to the third emission opening PDL-OPB.

Referring to FIG. 6A, a spacing distance between the 2-2^{nd} emission opening PDL-OPG2 and the second line section LA2 may be different from that between the first emission opening PDL-OPR and the second line section LA2. The second line section LA2 may be spaced apart at a second distance B1 from the first emission opening PDL-OPR. The second line section LA2 may be spaced apart at a third distance C1 from the 2-2^{nd} emission opening PDL-OPG2.

The second distance B1 may be less than the first distance A1. The third distance C1 may be greater than the first distance A1. The first distance A1 may correspond to an average of the second distance B1 and the third distance C1. The second distance B1 may be less by about 2 micrometers to about 8 micrometers than the third distance C1. When the first line section LA1 and the second line section LA2 are compared with each other, it may be observed that the second line section LA2 is shifted closer to the first emission opening PDL-OPR than the first line section LA1 is.

As the second line section LA2 is disposed relatively close to the first emission opening PDL-OPR, the second line section LA2 may block a relatively large amount of first source light (see, e.g., L-R of FIG. 6B) provided in a direction from the first color emission region PXA-R toward the second measurement point P135.

Referring to FIG. 6B, the second line section LA2 may block the first source light L-R that travels toward the fourth site P-4 having a viewing angle of 60° of the second measurement point P135. The second line section LA2 may not block propagation of light to sites each of which has a viewing angle less than that of the fourth site P-4, or to the third site P-3 having a viewing angle of 45°.

As the second line section LA2 is disposed close to the first emission opening PDL-OPR at the second distance B1 less than the first distance A1, there may be an increase in area of either the first emission opening PDL-OPR shielded by the second line section LA2 or the first color emission region PXA-R shielded by the second line section LA2. When referring to FIG. 3B, the increase in area of the first color emission region PXA-R shielded by the second line section LA2 may be the same as that in area of the first electrode AE, which is included in the light emitting element LD, shielded by the second line section LA2. This may be caused by the fact that the emission region PXA is defined to indicate a region of the first electrode AE exposed by the emission opening PDL-OP.

Referring to FIG. 6C, a second graph GP200 may correspond to the second graph GP200 of FIG. 5C. A 2-1^{st} graph GP200-1, a 2-2^{nd} graph GP200-2, and a 2-3^{rd} graph GP200-3 may indicate a color-coordinate variation (Δu′, Δv′) in accordance with a reduction in the second distance B1 and an increase in the third distance C1 of FIG. 6A. As can be observed from the 2-1^{st} graph GP200-1, the 2-2^{nd} graph GP200-2, and the 2-3^{rd} graph GP200-3, color coordinates of a white image were measured while changing a viewing angle at the second measurement point (see, e.g., P135 of FIGS. 6A and 6B) having an azimuthal angle of 135°.

For example, the second distance B1 may decrease by about 1 micrometer as seen in the sequence from the 2-1^{st} graph GP200-1 to the 2-3^{rd} graph GP200-3. The second graph GP200, the 2-1^{st} graph GP200-1, the 2-2^{nd} graph GP200-2, and the 2-3^{rd} graph GP200-3 were obtained from measurements under the condition of the same azimuthal angle and the same viewing angle.

Referring to the second graph GP200, the 2-1^{st} graph GP200-1, the 2-2 nd graph GP200-2, and the 2-3^{rd} graph GP200-3, a reduction in the second distance B1 may cause an increase in the degree to which the second line section LA2 blocks the first source light L-R as discussed with reference to FIG. 6B, which may result in a reduction in variation Δu′ at a viewing angle of 60°. According to the 2-2^{nd} graph GP200-2, there may be a variation Δu′ similar to that shown in the first graph GP100.

A first graph GP100 may correspond to the first graph GP100 of FIG. 5C. A 1-1^{st} graph GP100-1, a 1-2^{nd} graph GP100-2, and a 1-3^{rd} graph GP100-3 may indicate a color-coordinate variation (Δu′, Δv′) in accordance with a reduction in the second distance B1 and an increase in the third distance C1 of FIG. 6A. Unlike the second graph GP200, the 2-1^{st} graph GP200-1, the 2-2^{nd} graph GP200-2, and the 2-3^{rd} graph GP200-3, as can be understood from the 1-1^{st} graph GP100-1, the 1-2^{nd} graph GP100-2, and the 1-3^{rd} graph GP100-3, color coordinates of a white image were measured while changing a viewing angle at the first measurement point (see P90 of FIGS. 6A and 6B) having an azimuthal angle of 90°.

The situation that the reduction in the second distance B1 causes the increase in the degree to which the second line section LA2 blocks the first source light L-R may be found not only at the second measurement point P135 having an azimuthal angle of 135°, but also at the first measurement point P90 having an azimuthal angle of 90°. This may be caused by the fact that the second line section LA2 extends along an azimuthal angle of 90° and then an azimuthal angle of 180°.

As shown in the 2-2^{nd} graph GP200-2, there may be a reduction in red wavelength shift of a white image at a site having an azimuthal angle of 135° and a viewing angle of 60°, however, as shown in the 1-2^{nd} graph GP100-2, there may be an occurrence of yellow wavelength shift of a white image at a site having an azimuthal angle of 90° and a viewing angle of 60°. This may be caused by the fact that the blocking effect of the first source light L-R by the second line section LA2 causes an insufficient propagation of the first source light L-R to the site having an azimuthal angle of 90° and a viewing angle of 60°.

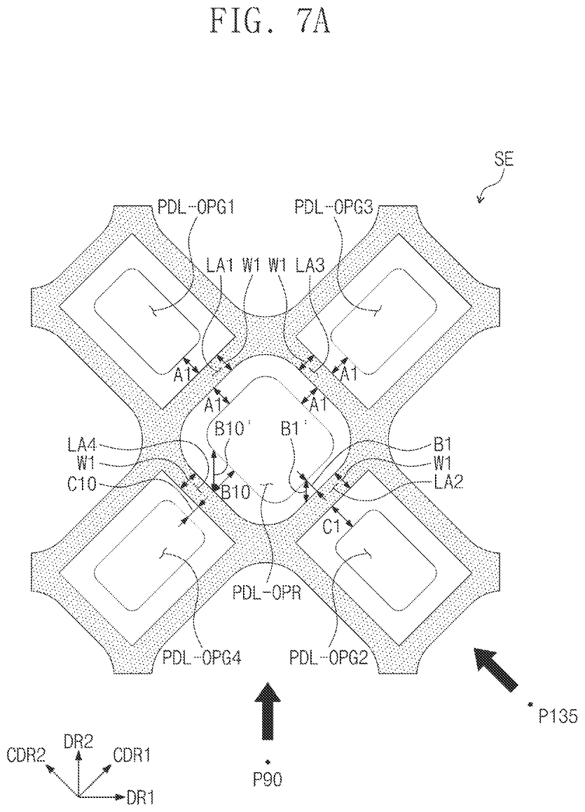

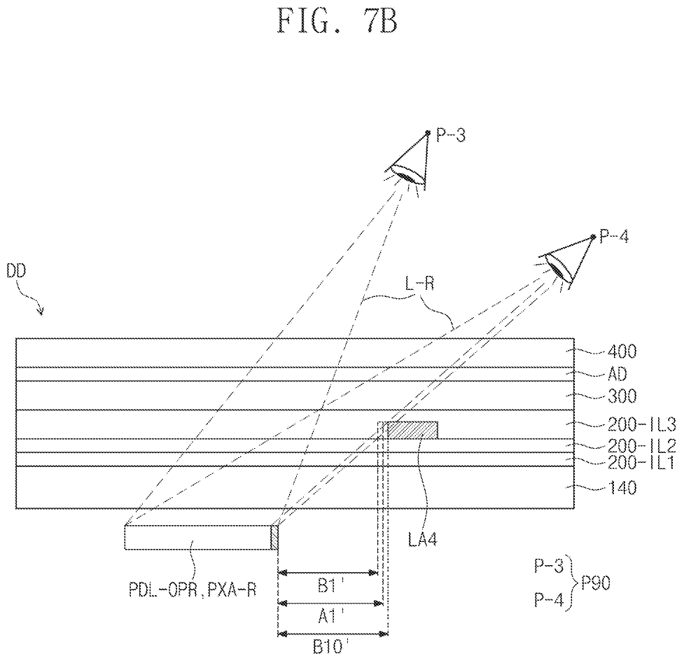

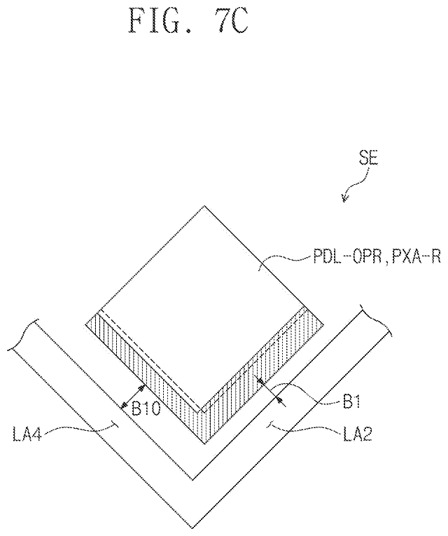

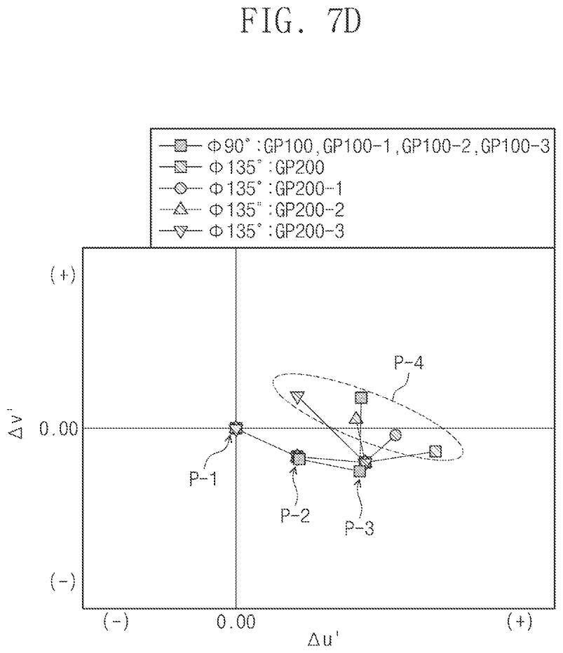

FIG. 7A illustrates a plan view showing an arrangement relationship between the emission openings PDL-OPR, PDL-OPG, and PDL-OPB and the sensing electrode SE according to some embodiments of the present invention. FIG. 7B illustrates a cross-sectional view showing an emission path of first source light according to some embodiments of the present invention. FIG. 7C illustrates a plan view showing a region shielded by a sensing electrode when a first emission region is seen from a first measurement point according to some embodiments of the present invention. FIG. 7D illustrates a graph showing a variation in color coordinate of a white image displayed on a display device according to some embodiments of the present invention. The following will focus on a difference between the present embodiments and the arrangement relationship between the emission openings PDL-OPR, PDL-OPG, and PDL-OPB and the sensing electrode SE shown in FIG. 6A.

Assuming that a reddish white image is measured, FIG. 7A depicts the sensing electrode SE for reducing a red wavelength shift of a white image. The sensing electrode SE according to some embodiments is configured such that the 1-1^{st} line section LA10, the 2-1^{st} line section LA20, the 3-1^{st} line section LA30, the 4-1^{st} line section LA40, and the third emission opening PDL-OPB are disposed to have an arrangement relationship that is the same as that shown in FIG. 5B.

When a bluish white image is measured, the sensing electrode SE that reduces a blue wavelength shift of a white image may have an arrangement relationship of the 1-1^{st} line section LA10, the 2-1^{st} line section LA20, the 3-1^{st} line section LA30, and the 4-1^{st} line section LA40 with respect to the third emission opening PDL-OPB, and the arrangement relationship may be different from that shown in FIG. 5B. As discussed below, the sensing electrode SE may have an arrangement relationship of the first line section LA1, the second line section LA2, the third line section LA3, and the fourth line section LA4 with respect to the first emission opening PDL-OPR, and the arrangement relationship may be applied to an arrangement relationship of the 1-1^{st} line section LA10, the 2-1^{st} line section LA20, the 3-1^{st} line section LA30, and the 4-1^{st} line section LA40 with respect to the third emission opening PDL-OPB.

Referring to FIG. 7A, a spacing distance between the 2-4^{th} emission opening PDL-OPG4 and the fourth line section LA4 may be different from that between the first emission opening PDL-OPR and the fourth line section LA4. The fourth line section LA4 may be spaced apart at a fourth distance B10 from the first emission opening PDL-OPR. The fourth line section LA4 may be spaced apart at a fifth distance C10 from the 2-4^{th} emission opening PDL-OPG4.

The fourth distance B10 may be greater than the first distance A1. The fifth distance C10 may be less than the first distance A1. When the third line section LA3 and the fourth line section LA4 are compared with each other, it may be observed that the fourth line section LA4 is shifted farther from the first emission opening PDL-OPR than the third line section LA3 is.

As the fourth line section LA4 is disposed relatively farther from the first emission opening PDL-OPR, there may be a reduction in the degree to which the fourth line section LA4 blocks the first source light L-R with respect to the first measurement point P90.

Referring to FIGS. 6A, 7A, and 7B, when the fourth line section LA4 is spaced apart at the first distance A1 from the first emission opening PDL-OPR, the fourth line section LA4 may be spaced apart at a 1-1^{st} distance A1′ from the first emission opening PDL-OPR when viewed from the first measurement point P90. When the fourth line section LA4 is spaced apart at the fourth distance B10 from the first emission opening PDL-OPR, the fourth line section LA4 may be spaced apart at a 4-1^{st} distance B10′ from the first emission opening PDL-OPR when viewed from the first measurement point P90.

In an example that the fourth line section LA4 is spaced apart at the 1-1^{st} distance A1′ from the first emission opening PDL-OPR when viewed from the first measurement point P90, the fourth line section LA4 may block the first source light L-R that travels toward the fourth site P-4 having a viewing angle of 60° of the first measurement point P90. In a case that the fourth line section LA4 is spaced apart at the 4-1^{st} distance B10′ from the first emission opening PDL-OPR when viewed from the first measurement point P90, the blocking effect of the first source light L-R by the fourth line section LA4 may be reduced or eliminated. FIG. 7B depicts a reduction in the degree to which the fourth line section LA4 blocks the first source light L-R.

When the second line section LA2 is spaced apart at the second distance B1 (e.g., from the first emission opening PDL-OPR) as shown in FIG. 6A, the second line section LA2 viewed from the first measurement point P90 may be spaced apart at a 2-1^{st} distance B1′ from the first emission opening PDL-OPR. When the fourth line section LA4 is also spaced apart at the second distance B1 from the first emission opening PDL-OPR, the fourth line section LA4 viewed from the first measurement point P90 may be spaced apart at the 2-1^{st} distance B1′ from the first emission opening PDL-OPR as shown in FIG. 7B.

An area of the first color emission region PXA-R shielded by the second line section LA2 and an area of the first color emission region PXA-R shielded by the fourth line section LA4 may depend on a spacing distance of the second line section LA2 from the first color emission region PXA-R and a spacing distance of the fourth line section LA4 from the first color emission region PXA-R. When the second line section LA2 and the fourth line section LA4 are spaced apart at the same distance from the first color emission region PXA-R, the area of the first color emission region PXA-R shielded by the second line section LA2 may be substantially the same as the area of the first color emission region PXA-R shielded by the fourth line section LA4.

An area of the first color emission region PXA-R that is shielded by the fourth line section LA4 may be formed toward the first measurement point P90 when the fourth line section LA4 is disposed at the fourth distance B10 (e.g., from the first color emission region PXA-R), and an area of the first color emission region PXA-R that is shielded by the second line section LA2 may be formed toward the first measurement point P90 when the second line section LA2 is disposed at the second distance B1 (e.g., from the first color emission region PXA-R). The area of the first color emission region PXA-R shielded by the fourth line section LA4 may be less than the area of the first color emission region PXA-R shielded by the second line section LA2.

FIG. 7C depicts a region shielded by the second line section LA2 and the fourth line section LA4 when the first emission region PXA-R is viewed from the first measurement point P90. For ease of illustration, the intersection region CA is omitted, and the sensing electrode SE is simply illustrated. In FIG. 7C, a dotted line is used to indicate a region shielded by the second line section LA2 and the fourth line section LA4 in examples in which the second line section LA2 and the fourth line section LA4 are spaced apart at the same distance (e.g., the first distance A1 of FIG. 7A) from the first emission region PXA-R.

FIG. 7C also illustrates examples in which the second line section LA2 is spaced apart at the second distance B1 from the first emission opening PDL-OPR and the fourth line section LA4 is spaced apart at the fourth distance B10 from the first emission opening PDL-OPR, whereby a region shielded by the second line section LA2 and the fourth line section LA4 is shown with hatchings when the first emission region PXA-R is viewed from the first measurement point P90. An area of the hatched region shielded by the second line section LA2 may be increased compared to the region depicted with the dotted line, and an area of the hatched region shielded by the fourth line section LA4 may be reduced compared to the region depicted with the dotted line.

Referring to FIGS. 7A to 7C, although an amount of the first source light L-R directed toward the first measurement point P90 is reduced due to the fact that the second line section LA2 is disposed at the second distance B1 from a certain emission opening (e.g., the first emission region PXA-R), the fourth line section LA4 may be disposed at the fourth distance B10 from the certain emission opening (e.g., the first emission region PXA-R) to compensate for the amount of the first source light L-R directed toward the first measurement point P90.

Referring to FIG. 7D, a second graph GP200, a 2-1^{st} graph GP200-1, a 2-2 nd graph GP200-2, and a 2-3^{rd} graph GP200-3 may be respectively the same as the second graph GP200, the 2-1^{st} graph GP200-1, the 2-2^{nd} graph GP200-2, and the 2-3^{rd} graph GP200-3 that are shown in FIG. 6C. A first graph GP100 may correspond to the first graph GP100 of FIG. 6C. The 1-1^{st} graph GP100-1, the 1-2^{nd} graph GP100-2, and the 1-3^{rd} graph GP100-3 of FIG. 6C may be substantially the same as the first graph GP100 of FIG. 7C and may thus be depicted as a single graph. In conclusion, because the fourth line section LA4 is spaced apart at the fourth distance B10 from the first emission opening PDL-OPR, the first source light L-R additionally provided to the fourth site P-4 having a viewing angle of 60° of the first measurement point P90 may compensate for the first source light L-R by an amount equal to that shielded by the second line section LA2.

With reference to FIGS. 7A to 7D, the above describes the yellow wavelength shift of the white image at the first measurement point P90 having an azimuthal angle of 90° in accordance with a positional change of the second line section LA2. The yellow wavelength shift of the white image may also be measured at a measurement point having an azimuthal angle of 180° in accordance with a positional change of the second line section LA2.

According to some embodiments of the present invention, the third line section LA3 of FIG. 7A may be spaced apart at the fourth distance B10 from the first emission opening PDL-OPR so as to also prevent or substantially reduce the yellow wavelength shift of the white image at the measurement point having an azimuthal angle of 180°. As the third line section LA3 is distally spaced apart from the first emission opening PDL-OPR, a large amount of the first source light may be provided to the measurement point having an azimuthal angle of 180°. Accordingly, the yellow wavelength shift of the white image may be reduced or eliminated.

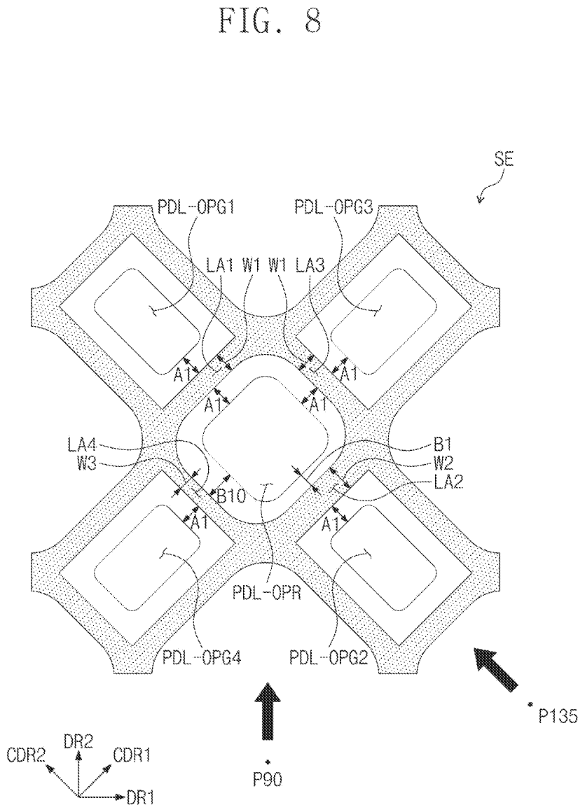

FIG. 8 illustrates a plan view showing an arrangement relationship between the emission openings PDL-OPR, PDL-OPG, and PDL-OPB and the sensing electrode SE according to some embodiments of the present invention. The following will focus on one or more differences between the present embodiments and the arrangement relationship between the emission openings PDL-OPR, PDL-OPG, and PDL-OPB and the sensing electrode SE shown in FIGS. 7A to 7C.

According to the some embodiments, each of the first, second, third, and fourth line sections LA1, LA2, LA3, and LA4 may be spaced apart at the first distance A1 from a corresponding one of four second emission openings PDL-OPG1 to PDL-OPG4.

The second line section LA2 may be spaced apart at the second distance B1 from the first emission opening PDL-OPR. A line-width W2 of the second line section LA2 may increase to reduce a spacing distance between the second line section LA2 and the first emission opening PDL-OPR. The line-width W2 of the second line section LA2 may be less than the line-width W1 of the first line section LA1.

The fourth line section LA4 may be spaced apart at the fourth distance B10 from the first emission opening PDL-OPR. A line-width W3 of the fourth line section LA4 may decrease to increase a spacing distance between the fourth line section LA4 and the first emission opening PDL-OPR. The line-width W3 of the fourth line section LA4 may be greater than the line-width W1 of the first line section LA1.

According to that discussed above, it may be possible to reduce a wavelength shift of a white image that is differently perceived based on the viewing angle. As a result, a display device may increase in display quality (e.g., color accuracy).

Although the embodiments have been described with reference to a number of illustrative examples thereof, it will be understood by those of ordinary skill in the art that various suitable changes in form and detail may be made without departing from the spirit and scope of the present invention as defined the following claims and equivalents thereof.

Thus, the technical scope of the present invention is not limited by the embodiments and examples described above, and is defined by the following claims and equivalents thereof.

What is claimed is:

1. A display device comprising:
a base layer having a display region defined along a first direction and a second direction that are orthogonal to each other;
a plurality of first light emitting elements on the base layer, wherein each one of the first light emitting elements comprises a first electrode, a second electrode on the first electrode, and a first emission layer between the first electrode and the second electrode;
a pixel definition layer having a plurality of first emission openings each of which exposes the first electrode of a corresponding first light emitting element of the first light emitting elements;
a thin encapsulation layer that covers the first light emitting elements and the pixel definition layer; and
a sensing electrode on the thin encapsulation layer, wherein the sensing electrode comprises a conductive line that defines a plurality of first opening each corresponding to one of the first emission openings and each having an area greater than an area of each of the first emission openings,
wherein the conductive line comprises a first line section, a second line section, a third line section, and a fourth line section that correspond to one of the first emission openings,
wherein the first line section and the second line section extend in a first diagonal direction that crosses the first direction and the second direction, the first line section and the second line section being spaced apart from each other in a second diagonal direction that is orthogonal to the first diagonal direction, a corresponding first emission opening of the first emission openings being between the first line section and the second line section in the second diagonal direction,
wherein the third line section and the fourth line section extend in the second diagonal direction and are spaced apart from each other in the first diagonal direction, the corresponding first emission opening being between the first line section and the second line section in the second diagonal direction, and
wherein a spacing distance between the second line section and the corresponding first emission opening is less than a spacing distance between the fourth line section and the corresponding first emission opening.

2. The display device of claim 1, wherein the first direction extends at azimuthal angles of 0° and 180°, and
when the first electrode of the corresponding first light emitting element is viewed at an azimuthal angle of 90° and a viewing angle of 60°, an area of the first electrode that is shielded by the second line section is greater than an area of the first electrode that is shielded by the fourth line section.

3. The display device of claim 1, wherein the first line section, the second line section, the third line section, and the fourth line section have substantially the same line-width.

4. The display device of claim 3, wherein an intersection region is between adjacent line sections of the first line section, the second line section, the third line section, and the fourth line section, and
wherein the intersection region has a line-width greater than line-widths of the adjacent line sections.

5. The display device of claim 1, wherein the fourth line section has a line-width less than a line-width of the second line section.

6. The display device of claim 5, wherein the line-width of the second line section is greater than a line-width of each of the first line section and the third line section, and
wherein the line-width of the fourth line section is less than the line-width of each of the first line section and the third line section.

7. The display device of claim 1, further comprising a plurality of second light emitting elements on the base layer,
wherein each of the second light emitting elements comprises a first electrode, a second electrode on the first electrode of the each of the second light emitting elements, and a second emission layer between the first and second electrodes of the each of the second light emitting elements,
wherein the pixel definition layer further comprises a plurality of second emission openings each of which exposes the first electrode of a corresponding second light emitting element of the second light emitting elements,
wherein the sensing electrode further comprises a plurality of second openings each corresponding to one of the second emission openings and each having an area greater than an area of each of the second emission openings,
wherein the conductive line further comprises a 1-1^{st} line section, a 2-1^{st} line section, a 3-1^{st} line section, and a 4-1^{st} line section that correspond to the second emission openings,
wherein the 1-1^{st} line section and the 2-1^{st} line section are spaced apart from each other in the second diagonal direction across a corresponding second emission opening of the second emission openings,
wherein the 3-1^{st} line section and the 4-1^{st} line section are spaced apart from each other in the first diagonal direction across the corresponding second emission opening, and
wherein the 1-1^{st} line section, the 2-1^{st} line section, the 3-1^{st} line section, and the 4-1^{st} line section are spaced apart at substantially the same distance from the corresponding second emission opening.

8. The display device of claim 7, wherein the first line section and the third line section are spaced apart at a first distance from the corresponding first emission opening, and
wherein the 1-1^{st} line section and the corresponding second emission opening are spaced apart at the first distance from each other.

9. The display device of claim 1, further comprising a plurality of second light emitting elements on the base layer,
wherein each of the second light emitting elements comprises a first electrode, a second electrode on the first electrode of the each of the second light emitting elements, and a second emission layer between the first and second electrodes of the each of the second light emitting elements,
wherein the second light emitting elements comprise a 2-1^{st} light emitting element, a 2-2^{nd} light emitting element, a 2-3^{rd} light emitting element, and a 2-4^{th} light emitting element that surround a corresponding first light emitting element of the first light emitting elements,
wherein the 2-1^{st} light emitting element and the 2-2^{nd} light emitting element are spaced apart from each other in the second diagonal direction across the corresponding first light emitting element surrounded by the 2-1^{st} light emitting element, the 2-2^{nd} light emitting element, the 2-3^{rd} light emitting element, and the 2-4^{th} light emitting element,
wherein the 2-3^{rd} light emitting element and the 2-4^{th} light emitting element are spaced apart from each other in the first diagonal direction across the corresponding first light emitting element surrounded by the 2-1^{st} light emitting element, the 2-2^{nd} light emitting element, the 2-3^{rd} light emitting element, and the 2-4^{th} light emitting element, and
wherein the pixel definition layer further comprises a 2-1^{st} emission opening, a 2-2^{nd} emission opening, a 2-3^{rd} emission opening, and a 2-4^{th} emission opening that respectively expose the first electrode of the 2-1^{st} light emitting element, the first electrode of the 2-2^{nd} light emitting element, the first electrode of the 2-3^{rd} light emitting element, and the first electrode of the 2-4^{th} light emitting element.

10. The display device of claim 9, wherein the first line section is between the corresponding first emission opening and the 2-1^{st} emission opening,
wherein the second line section is between the corresponding first emission opening and the 2-2^{nd} emission opening,
wherein the third line section is between the corresponding first emission opening and the 2-3^{rd} emission opening, and
wherein the fourth line section is between the corresponding first emission opening and the 2-4^{th} emission opening.

11. The display device of claim 10, wherein the first line section and the third line section are spaced apart at a first distance from the corresponding first emission opening,
wherein the first line section is spaced apart at the first distance from the 2-1^{st} emission opening, and
wherein the third line section is spaced apart at the first distance from the 2-3^{rd} emission opening.

12. The display device of claim 11, wherein the second line section is spaced apart from the 2-2^{nd} emission opening at a distance greater than the first distance, and
wherein the fourth line section is spaced apart from the 2-4^{th} emission opening at a distance less than the first distance.

13. The display device of claim 1, wherein each of the first emission openings has a substantially tetragonal shape in a plan view.

14. The display device of claim 13, wherein each of the first emission openings is defined by a first edge, a second edge, a third edge, and a fourth edge,
wherein the first edge and the second edge extend in the first diagonal direction and face each other in the second diagonal direction, and
wherein the third edge and the fourth edge extend in the second diagonal direction and face each other in the first diagonal direction.

15. The display device of claim 1, wherein each of the first light emitting elements generates red light.

16. A display device comprising:
a base layer having a display region defined by a first direction and a second direction that are orthogonal to each other;
a first light emitting element configured to generate a first source light;
a 2-1^{st} light emitting element, a 2-2^{nd} light emitting element, a 2-3^{rd} light emitting element, and a 2-4^{th} light emitting element each of which is configured to generate a second source light and which surround the first light emitting element;
a pixel definition layer that comprises a first emission opening and a plurality of second emission openings, the first emission opening corresponding to the first light emitting element, the second emission openings corresponding to the 2-1^{st} light emitting element, the 2-2^{nd} light emitting element, the 2-3^{rd} light emitting element, and the 2-4^{th} light emitting element;
a thin encapsulation layer that covers the first light emitting element, the 2-1^{st} light emitting element, the 2-2^{nd} light emitting element, the 2-3^{rd} light emitting element, the 2-4^{th} light emitting element, and the pixel definition layer; and
a sensing electrode on the thin encapsulation layer, and comprising a conductive line comprising a first aperture corresponding to the first emission opening and a plurality of second opening that correspond to the second emission openings, the first aperture having an area greater than an area of the first emission opening, and each of the second opening having an area greater than an area of each of the second emission openings,
wherein the conductive line comprises a first line section between the first light emitting element and the 2-1^{st} light emitting element, a second line section between the first light emitting element and the 2-2^{nd} light emitting element, a third line section between the first light emitting element and the 2-3^{rd} light emitting element, and a fourth line section between the first light emitting element and the 2-4^{th} light emitting element,
wherein the first line section and the second line section extend in a first diagonal direction that cross the first direction and the second direction,
wherein the third line section and the fourth line section extend in a second diagonal direction orthogonal to the first diagonal direction,
wherein at least one of the first line section and the third line section is spaced apart at a first distance from the first emission opening,
wherein the second line section is spaced apart from the first emission opening at a distance less than the first distance, and
wherein the fourth line section is spaced apart from the first emission opening at a distance greater than the first distance.

17. The display device of claim 16, wherein the first line section is spaced apart at the first distance from one of the second emission openings that corresponds to the 2-1^{st} light emitting element, and
wherein the third line section is spaced apart at the first distance from one of the second emission openings that corresponds to the 2-3^{rd} light emitting element.

18. The display device of claim 16, wherein the second line section is spaced apart at a distance greater than the first distance from one of the second emission openings that corresponds to the 2-2^{nd} light emitting element.

19. The display device of claim 16, wherein the fourth line section is spaced apart at a distance less than the first distance from one of the second emission openings that corresponds to the 2-4^{th} light emitting element.

20. The display device of claim 16, wherein the first line section, the second line section, the third line section, and the fourth line section have substantially the same line-width.
